(19) United States
(12) Patent Application Publication
(10) Pub. No.: US 2023/0420519 A1
(43) Pub. Date: Dec. 28, 2023

(54) SEMICONDUCTOR DEVICES

(71) Applicant: Samsung Electronics Co., Ltd., Suwon-si (KR)

(72) Inventors: Da Hye Kim, Suwon-si (KR); Gyeom Kim, Suwon-si (KR); Jin Bum Kim, Suwon-si (KR); Su Jin Jung, Suwon-si (KR); Kyung Bin Chun, Suwon-si (KR)

(21) Appl. No.: 18/110,950

(22) Filed: Feb. 17, 2023

(30) Foreign Application Priority Data
Jun. 22, 2022 (KR) 10-2022-0075952

(51) Int. Cl. H01L 29/08; H01L 29/06; H01L 29/161; H01L 29/423; H01L 29/775; H01L 21/02; H01L 29/66

(52) U.S. Cl. CPC H01L 29/0847; H01L 29/0673; H01L 29/161; H01L 29/42392; H01L 29/775; H01L 21/02532; H01L 29/66545; H01L 29/66439

(57) ABSTRACT

A semiconductor device having improved performance and reliability. The semiconductor device may include a lower pattern extending in a first direction, and a plurality of sheet patterns spaced apart from the lower pattern in a second direction perpendicular to the first direction. A plurality of gate structures may be on the lower pattern and spaced apart in the first direction, and a source/drain pattern, which may include a semiconductor liner film and a semiconductor filling film on the semiconductor liner film. A liner recess that is defined by an inner surface of the semiconductor liner film may include a plurality of width extension regions, and a width of each width extension region in the first direction may increase and then decreases, as a distance increases in the second direction from an upper surface of the lower pattern.

### CROSS-REFERENCE TO RELATED APPLICATION

This application claims priority from Korean Patent Application No. 10-2022-0075952 filed on Jun. 22, 2022, in the Korean Intellectual Property Office, and all the benefits accruing therefrom under 35 U.S.C. § 119, and the entire contents of the above-identified application are incorporated by reference herein.

### BACKGROUND

### Technical Field

The present disclosure relates to semiconductor devices, and more specifically, relates to semiconductor devices that include a MBCFET™ (Multi-Bridge Channel Field Effect Transistor).

### Description of the Related Art

One proposed scaling technology for increasing a density of semiconductor devices may utilize a multi gate transistor in which a multi-channel active pattern (or a silicon body) having a fin or nanowire shape is formed on a substrate and a gate is formed on a surface of the multi-channel active pattern.

Since such a multi gate transistor utilizes a three-dimensional channel, scaling may be performed more easily. Further, even if a gate length of the multi gate transistor is not increased, the current control capability may be improved. Furthermore, a SCE (short channel effect) in which potential of a channel region is influenced by a drain voltage may be effectively suppressed.

### SUMMARY

Some aspects of the present disclosure provide semiconductor devices having overall improved performance and reliability and/or improved performance and reliability of components of the semiconductor devices.

However, aspects of the present disclosure are not restricted to those set forth herein. The above and other aspects of the present disclosure will become more apparent to those of ordinary skill in the art to which the present disclosure pertains by referencing the detailed description of the present disclosure given below.

According to some aspects of the present disclosure, there is provided a semiconductor device comprising an active pattern which may include a lower pattern that extends in a first direction, and a plurality of sheet patterns spaced apart from the lower pattern in a second direction that is perpendicular to the first direction. The semiconductor device may include a plurality of gate structures which are on the lower pattern and spaced apart from each other in the first direction, and each gate structure including a gate electrode and a gate insulating film, and the semiconductor device may include a source/drain pattern which is between a pair of the gate structures adjacent to each other in the first direction. The source/drain pattern may include a semiconductor liner film and a semiconductor filling film on the semiconductor liner film, wherein the semiconductor liner film and the semiconductor filling film include silicon-germanium, and a germanium fraction of the semiconductor liner film is less than the germanium fraction of the semiconductor filling film. The semiconductor liner film may include an outer surface that is in contact with the sheet pattern, and an inner surface that faces the semiconductor filling film. A liner recess that is defined by the inner surface of the semiconductor liner film may include a plurality of width extension regions, and a width of each width extension region in the first direction increases and then decreases, as a distance increases in the second direction from an upper surface of the lower pattern.

According to some aspects of the present disclosure, there is provided a semiconductor device comprising an active pattern which may include a lower pattern that extends in a first direction, and a plurality of sheet patterns spaced apart from the lower pattern in a second direction that is perpendicular to the first direction. The semiconductor device may include a plurality of gate structures which are on the lower pattern and spaced apart from each other in the first direction, each gate structure including a gate electrode and a gate insulating film, and the semiconductor device may include a source/drain pattern which is between a pair of the gate structures that are adjacent to each other in the first direction. The source/drain pattern may include a semiconductor insertion film, and a semiconductor filling film on the semiconductor insertion film, where the semiconductor insertion film and the semiconductor filling film include silicon-germanium, and a germanium fraction of the semiconductor insertion film is less than the germanium fraction of the semiconductor filling film. The semiconductor insertion film may include an inner surface that is in contact with the semiconductor filling film, and an outer surface that faces the sheet pattern, the outer surface of the semiconductor insertion film may include a plurality of first convex curved regions and a plurality of first concave curved regions, and the outer surface of the semiconductor insertion film may not contact the sheet pattern.

According to some aspects of the present disclosure, there is provided a semiconductor device comprising an active pattern which may include a lower pattern that extends in a first direction, and a plurality of sheet patterns spaced apart from the lower pattern in a second direction that is perpendicular to the first direction. The semiconductor device may include a plurality of gate structures which are on the lower pattern and spaced apart from each other in the first direction, each gate structure including a gate electrode and a gate insulating film, and the semiconductor device may include a source/drain pattern which may be between a pair of the gate structures that are adjacent to each other in the first direction. The gate structure may include an inner gate structure which is between the lower pattern and the sheet pattern in the second direction, and between each pair of the sheet patterns adjacent to each other in the second direction, each inner gate structure including the gate electrode and the gate insulating film. The source/drain pattern may include a semiconductor liner film, a semiconductor filling layer on the semiconductor liner film, and a semiconductor insertion film between the semiconductor liner film and the semiconductor filling film, the semiconductor liner film. The semiconductor insertion film and the semiconductor filling film may include silicon-germanium, a germanium fraction of the semiconductor insertion film may be greater than a germanium fraction of the semiconductor liner film and less than a germanium fraction of the semiconductor filling film, the semiconductor liner film may include an outer surface which is in contact with the sheet pattern and the inner gate structure, and an inner surface which is in contact with the semiconductor insertion film, and the inner surface of the semiconductor liner film may include a plurality of convex curved regions and a plurality of concave curved regions.

### BRIEF DESCRIPTION OF DRAWINGS

The above and other aspects and features of the present disclosure will become more apparent by describing in detail illustrative embodiments thereof with reference to the attached drawings, in which:

FIG. 1 is an exemplary plan view for explaining a semiconductor device according to some embodiments;

FIGS. 2 and 3 are cross-sectional views taken along A-A and B-B of FIG. 1;

FIGS. 4 and 5 are plan views taken along C-C and D-D of FIG. 2;

FIG. 6 is a diagram for explaining shapes of a semiconductor liner film and a semiconductor insertion film of FIG. 2;

FIGS. 7 to 9 are enlarged views of a region P of FIG. 2 according to some embodiments;

FIG. 10 is a diagram for explaining a germanium fraction of a first source/drain pattern of FIG. 2;

FIGS. 11 and 12 are diagrams for explaining a semiconductor device according to some embodiments;

FIGS. 13 to 15 are diagrams for explaining a semiconductor device according to some embodiments;

FIG. 16 is a diagram for explaining a semiconductor device according to some embodiments;

FIGS. 17 and 18 are diagrams for explaining a semiconductor device according to some embodiments;

FIGS. 19 and 20 are diagrams for explaining the semiconductor device according to some embodiments;

FIGS. 21 and 22 are diagrams for explaining a semiconductor device according to some embodiments, respectively;

FIGS. 23 to 25 are diagrams for explaining a semiconductor device according to some embodiments;

FIGS. 26 to 32 are intermediate step diagrams for describing a method for fabricating a semiconductor device according to some embodiments.

### DETAILED DESCRIPTION OF THE EMBODIMENTS

A semiconductor device according to some embodiments may include a tunneling transistor (tunneling FET), a three-dimensional (3D) transistor or two-dimensional material-based transistor (2D material-based FETs), and/or a heterogeneous structure thereof. Further, the semiconductor device according to some embodiments may include a bipolar junction transistor, a laterally-diffused metal-oxide semiconductor (LDMOS), or the like.

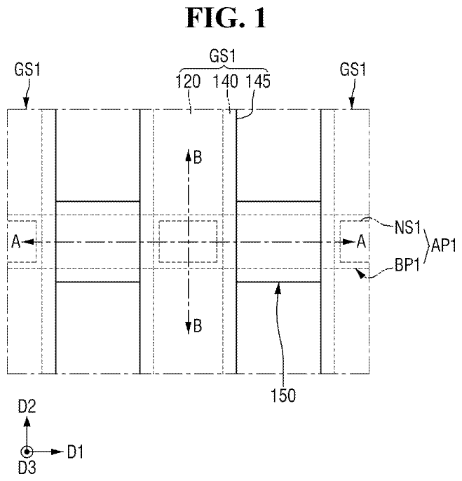

Some examples of semiconductor devices according to some embodiments will be described with reference to FIGS. 1 to 10.

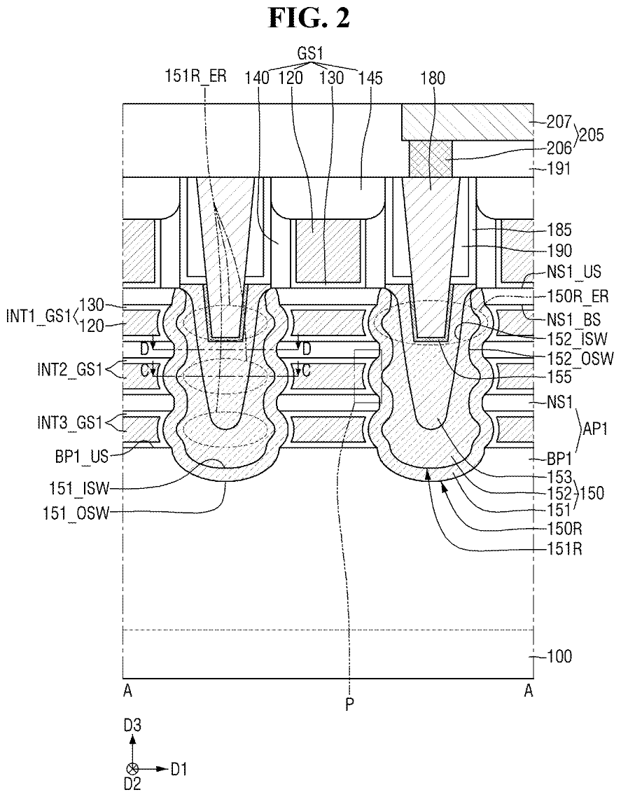

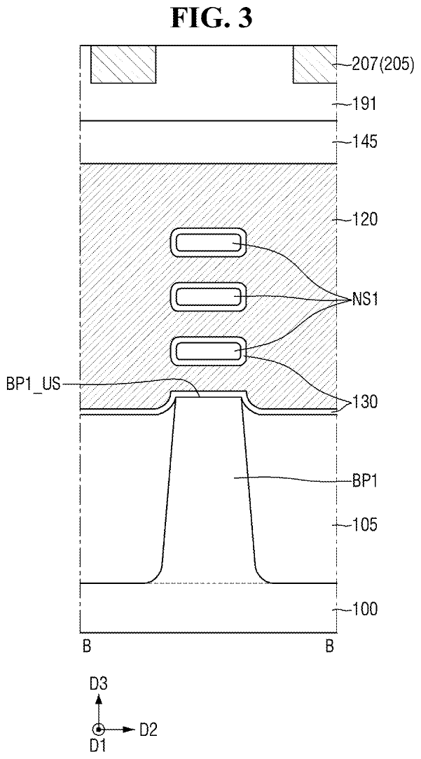

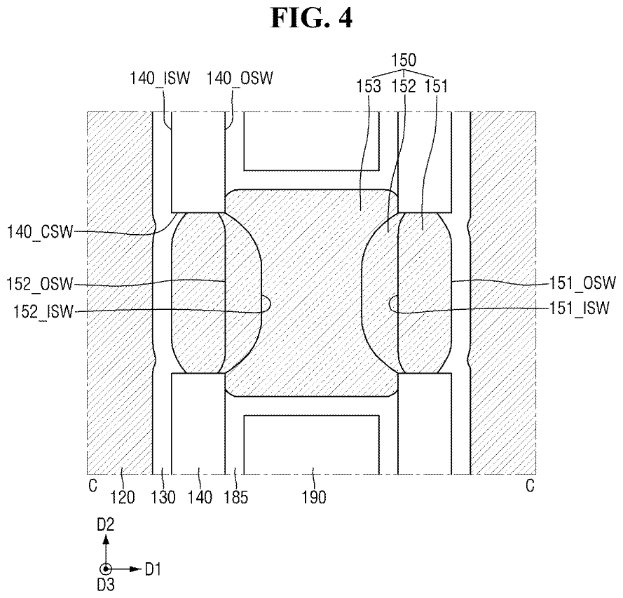

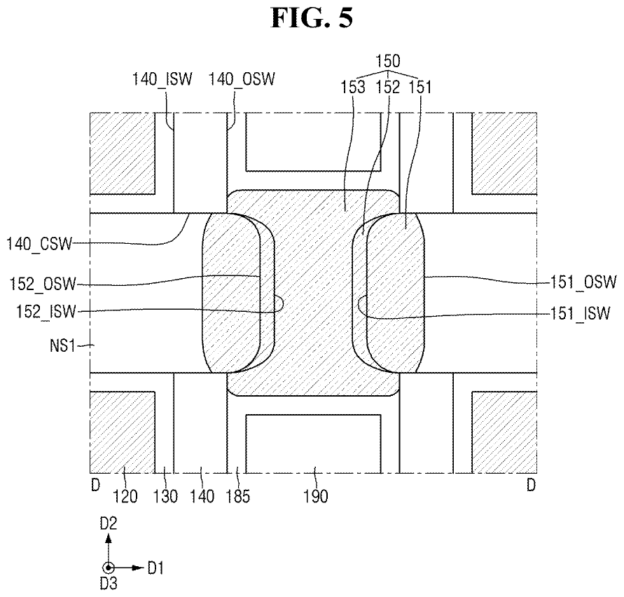

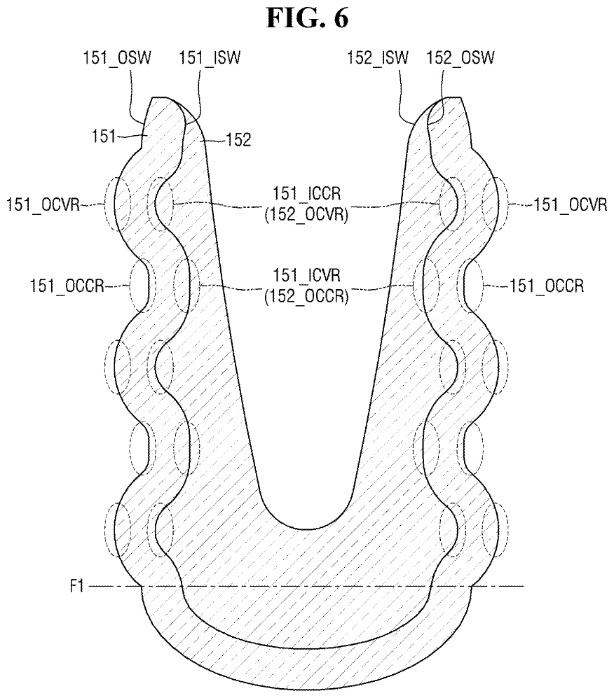

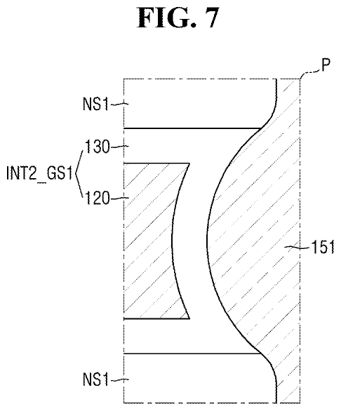

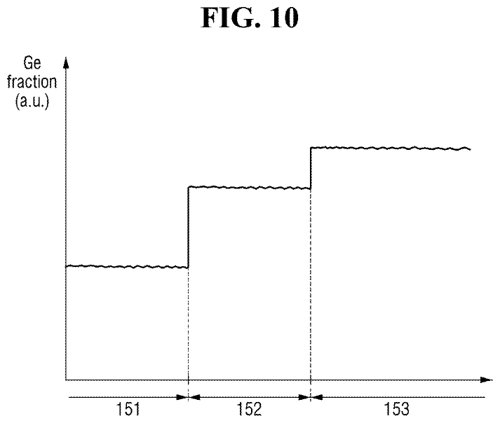

FIG. 1 is an exemplary plan view for explaining a semiconductor device according to some embodiments. FIGS. 2 and 3 are cross-sectional views taken along A-A and B-B of FIG. 1. FIGS. 4 and 5 are plan views taken along C-C and D-D of FIG. 2. FIG. 6 is a diagram for explaining shapes of a semiconductor liner film and a semiconductor insertion film of FIG. 2. FIGS. 7 to 9 are enlarged views of a region P of FIG. 2 according to some embodiments. FIG. 10 is a diagram for explaining a germanium fraction of a first source/drain pattern of FIG. 2.

For simplicity, some elements of the semiconductor device are not shown FIG. 1, such as a first gate insulating film 130, a first source/drain contact 180, a source/drain etch stop film 185, interlayer insulating films 190 and 191, a wiring structure 205, and the like.

Referring to FIGS. 1 to 10, the semiconductor device according to some embodiments may include a first active pattern AP1, a plurality of first gate electrodes 120, a plurality of first gate structures GS1, and a first source/drain pattern 150.

In some embodiments, the substrate 100 may be bulk silicon or silicon-on-insulator (SOI). In some embodiments, the substrate 100 may be a silicon substrate, or may include, but not limited to, other materials, for example, silicon germanium, SGOI (silicon germanium on insulator), indium antimonide, lead tellurium compounds, indium arsenic, indium phosphide, gallium arsenide or gallium antimonide.

A first active pattern AP1 may be on the substrate 100. The first active pattern AP1 may extend in length in a first direction D1. For example, the first active pattern AP1 may be in a region in which a PMOS is formed.

The first active pattern AP1 may be, for example, a multi-channel active pattern. The first active pattern AP1 may include a first lower pattern BP1 and a plurality of first sheet patterns NS1.

The first lower pattern BP1 may protrude from the substrate 100. The first lower pattern BP1 may extend in length in the first direction D1.

The plurality of first sheet patterns NS1 may be on an upper surface BP1_US of the first lower pattern. The plurality of first sheet patterns NS1 may be spaced apart from the first lower pattern BP1 in a third direction D3. The plurality of first sheet patterns NS1 may be spaced apart from each other in the third direction D3. Each first sheet pattern NS1 may include an upper surface NS1_US and a lower surface NS1_BS. The upper surface NS1_US of the first sheet pattern NS1 is a surface that is opposite to the lower surface NS1_BS of the first sheet pattern NS1 in the third direction D3.

The first direction D1 and a second direction D2 may be parallel to an upper or lower surface of the substrate 100, and the third direction D3 may be perpendicular and/or intersecting the first direction D1 and the second direction D2. For example, the third direction D3 may be a thickness direction of the substrate 100. The first direction D1 may be a direction that intersects the second direction D2.

Although FIGS. 1-10 show three first sheet patterns NS1 arranged in the third direction D3, the example is only for convenience of explanation and the present disclosure is not limited thereto.

The first lower pattern BP1 may be formed by etching a part of the substrate 100, or may include an epitaxial layer grown from the substrate 100. The first lower pattern BP1 may include silicon or germanium, which is an elemental semiconductor material. Also, the first lower pattern BP1 may include a compound semiconductor, and may include, for example, a group IV-IV compound semiconductor or a group III-V compound semiconductor.

The group IV-IV compound semiconductor may be, for example, a binary compound or a ternary compound including at least two or more of carbon (C), silicon (Si), germanium (Ge) and tin (Sn), or a compound obtained by doping these elements with a group IV element.

The group III-V compound semiconductor may be, for example, one of a binary compound, a ternary compound or a quaternary compound formed by combining at least one of aluminum (Al), gallium (Ga) and indium (In) as a group III element with one of phosphorus (P), arsenic (As) and antimony (Sb) as a group V element.

Each first sheet pattern NS1 may include one of silicon or germanium, which is an elemental semiconductor material, a group IV-IV compound semiconductor, or a group III-V compound semiconductor. Each first sheet pattern NS1 may include the same material as the first lower pattern BP1, or may include a different material from the first lower pattern BP1.

In some embodiments, the first lower pattern BP1 may be a silicon lower pattern including silicon, and the first sheet pattern NS1 may be a silicon sheet pattern including silicon.

In some embodiments, a width of each first sheet pattern NS1 in the second direction D2 may increase or decrease in proportion to a width of the first lower pattern BP1 in the second direction D2 and a distance in the third direction D3 between the first sheet pattern NS1 and the first lower pattern BP1. In other words, although FIG. 3 shows the first sheet patterns NS1 stacked in the third direction D3 to have the same width in the second direction D2, this example is only for convenience of explanation and the present disclosure is not limited thereto. In some embodiments, and in contrast to the shown example, the width in the second direction D2 of the first sheet patterns NS1 stacked in the third direction D3 may decrease, as it goes away from the first lower pattern BP1.

As seen in FIG. 3, a field insulating film 105 may be formed on the substrate 100. The field insulating film 105 may be on the side walls of the first lower pattern BP1. The field insulating film 105 may be absent from the upper surface BP1_US of the first lower pattern BP1.

In some embodiments, and as seen in FIG. 3, the field insulating film 105 may entirely cover the side walls of the first lower pattern BP1 in a direction (e.g., the second direction D2). In some embodiments, and in contrast to the shown example, the field insulating film 105 may cover only a portion of the side walls of the first lower pattern BP1 in the direction (e.g., the second direction D2). In such a case, a part of the first lower pattern BP1 may protrude from the upper surface of the field insulating film 105 in the third direction D3.

Each first sheet pattern NS1 may be arranged to be higher than the upper surface of the field insulating film 105. Each first sheet pattern NS1 may be arranged to be farther from the upper surface of the substrate 100 than the upper surface of the field insulating film 105 is from the upper surface of the substrate 100. The field insulating film 105 may include, for example, an oxide film, a nitride film, an oxynitride film or a combination thereof. Although the field insulating film 105 is shown as a single film, this example is only for convenience of explanation and the present disclosure is not limited thereto.

A plurality of first gate structures GS1 may be on the substrate 100. Each first gate structure GS1 may extend in length in the second direction D2. The first gate structures GS1 may be spaced apart in the first direction D1. The first gate structures GS1 may be adjacent to each other in the first direction D1. For example, the first gate structure GS1 may be provided on first and second sides of the first source/drain pattern 150 in the first direction D1.

The first gate structure GS1 may be on the first active pattern AP1. The first gate structure GS1 may intersect or cross the first active pattern AP1.

The first gate structure GS1 may intersect or cross the first lower pattern BP1. The first gate structure GS1 may wrap the respective first sheet patterns NS1.

The first gate structure GS1 may include, for example, a first gate electrode 120, a first gate insulating film 130, a first gate spacer 140, and a first gate capping pattern 145.

The first gate structure GS1 may include a plurality of inner gate structures INT1_GS1, INT2_GS1 and INT3_GS1 between the first sheet patterns NS1 adjacent to each other in the third direction D3, and between the first lower pattern BP1 and the first sheet pattern NS1. The inner gate structures INT1_GS1, INT2_GS1 and INT3_GS1 may be between the upper surface BP1_US of the first lower pattern BP1 and the lower surface NS1_BS of the first lowermost sheet pattern NS1, and between the upper surface NS1_US of a lower first sheet pattern NS1 and the lower surface NS1_BS of a higher first sheet pattern NS1 that face each other in the third direction D3.

A number of inner gate structures INT1_GS1, INT2_GS1 and INT3_GS1 may be proportional to a number of first sheet patterns NS1 included in the first active pattern AP1. For example, the number of inner gate structures INT1_GS1, INT2_GS1 and INT3_GS1 may be the same as or equal to the number of first sheet patterns NS1. Since the first active pattern AP1 may include a plurality of first sheet patterns NS1, the first gate structure GS1 may include a plurality of inner gate structures.

The inner gate structures INT1_GS1, INT2_GS1 and INT3_GS1 may be in contact with the upper surface BP1_US of the first lower pattern, the upper surface NS1_US of a first sheet pattern NS1, and/or the lower surface NS BS of a first sheet pattern NS1.

The inner gate structures INT1_GS1, INT2_GS1 and INT3_GS1 may be in contact with a first source/drain pattern 150 which will be described in greater detail below. For example, the inner gate structures INT1_GS1, INT2_GS1 and INT3_GS1 may be in direct contact with the first source/drain pattern 150.

The following description will be provided, using a example case where the number of inner gate structures INT1_GS1, INT2_GS1 and INT3_GS1 is three.

The first gate structure GS1 may include a first inner gate structure INT1_GS1, a second inner gate structure INT2_GS1, and a third inner gate structure INT3_GS1. The first inner gate structure INT1_GS1, the second inner gate structure INT2_GS1 and the third inner gate structure INT3_GS1 may be sequentially arranged on the first lower pattern BP1.

The third inner gate structure INT3_GS1 may be between the first lower pattern BP1 and the first sheet pattern NS1. The third inner gate structure INT3_GS1 may be arranged at the lowermost part among the inner gate structures INT1_GS1, INT2_GS1 and INT3_GS1. The third inner gate structure INT3_GS1 may be the lowermost inner gate structure.

The first inner gate structure INT1_GS1 and the second inner gate structure INT2_GS1 may be between pairs of the first sheet patterns NS1 adjacent to each other in the third direction D3. The first inner gate structure INT1_GS1 may be at the uppermost part among the inner gate structures INT1_GS1, INT2_GS1 and INT3_GS1. The first inner gate structure INT1_GS1 may be the uppermost inner gate structure. The second inner gate structure INT2_GS1 may be between the first inner gate structure INT1_GS1 and the third inner gate structure INT3_GS1.

The inner gate structures INT1_GS1, INT2_GS1 and INT3_GS1 may each include a first gate electrode 120 and a first gate insulating film 130 between adjacent first sheet patterns NS1, and between the first lower pattern BP1 and the first sheet pattern NS1.

In some embodiments, the width (e.g., a maximum width) of the first inner gate structure INT1_GS1 in the first direction D1 may be the same as the width (e.g., a maximum width) of the second inner gate structure INT2_GS1 in the first direction D1. The width (e.g., a maximum width) of the third inner gate structure INT3_GS1 in the first direction D1 may be the same as the width (e.g., the maximum width) of the second inner gate structure INT2_GS1 in the first direction D1.

As another example, the width of the third inner gate structure INT3_GS1 in the first direction D1 may be greater than the width of the second inner gate structure INT2_GS1 in the first direction D1. The width of the first inner gate structure INT1_GS1 in the first direction D1 may be the same as the width of the second inner gate structure INT2_GS1 in the first direction D1.

The second inner gate structure INT2_GS1 will be described as an example. The width of the second inner gate structure INT2_GS1 may be measured in the middle between (e.g., equidistant from) the upper surface NS1_US of the first sheet pattern below the second inner gate structure INT2_GS1 and the lower surface NS BS of the first sheet pattern above the second inner gate structure INT2_GS1, the surfaces of the first sheet patterns facing each other in the third direction D3.

For reference, a plan view at the level of the second inner gate structure INT2_GS1 is shown in FIG. 4. Although not shown, when the portion in which the first source/drain contact 180 is formed is excluded, the plan view at the level of other inner gate structures INT1_GS1 and INT3_GS1 may also be similar to FIG. 4.

FIG. 5 shows a plan view at the level of the first sheet pattern NS1 located at the center among the three first sheet patterns NS1. Although not shown, when the portion in which the first source/drain contact 180 is formed is excluded, the plan view at the level of another first sheet patterns NS1 may also be similar to FIG. 5.

The first gate electrode 120 may be formed on the first lower pattern BP1. The first gate electrode 120 may intersect or cross the first lower pattern BP1. The first gate electrode 120 may wrap the first sheet pattern NS1.

A part or portion of the first gate electrode 120 may be between the first sheet patterns NS1 adjacent to each other in the third direction D3. For example, when the first sheet pattern NS1 includes a lower sheet pattern and an upper sheet pattern adjacent to each other in the third direction D3, a part or portion of the first gate electrode 120 may be between the upper surface NS1_US of the first lower sheet pattern and the lower surface NS BS of the first upper sheet pattern facing each other. Also, a part or portion of the first gate electrode 120 may be between the upper surface BS1_US of the first lower pattern and the lower surface NS1_BS of the first lowermost sheet pattern.

The first gate electrode 120 may include at least one of metal, metal alloy, conductive metal nitride, metal silicide, doped semiconductor material, conductive metal oxide and conductive metal oxynitride. The first gate electrode 120 may include, but is not limited to, for example, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and/or combinations thereof. The conductive metal oxide and conductive metal oxynitride may include, but are not limited to, oxidized forms of the aforementioned materials.

The first gate electrode 120 may be on both sides of a first source/drain pattern 150, which will be described in greater detail below. First gate structures GS1 may be on first and second sides of the first source/drain pattern 150 in the first direction D1.

For example, both of the first gate electrodes 120 on the first and second sides of the first source/drain pattern 150 may be normal gate electrodes used as gates of transistors. As another example, one of the first gate electrodes 120 on one side of the first source/drain pattern 150 may be used as a gate of a transistor, but the other first gate electrode 120 on the other side of the first source/drain pattern 150 may be a dummy gate electrode.

The first gate insulating film 130 may extend along the upper surface of the field insulating film 105 and the upper surface BP1_US of the first lower pattern. The first gate insulating film 130 may wrap the plurality of first sheet patterns NS1. The first gate insulating film 130 may be along the periphery of the first sheet pattern NS1. The first gate electrode 120 may be on the first gate insulating film 130. The first gate insulating film 130 may be between the first gate electrode 120 and the first sheet pattern NS1. A part of the first gate insulating film 130 may be between the first sheet patterns NS1 adjacent in the third direction D3, and between the first lower pattern BP1 and the first sheet pattern NS1.

The first gate insulating film 130 may include silicon oxide, silicon-germanium oxide, germanium oxide, silicon oxynitride, silicon nitride, or a high dielectric constant material having a higher dielectric constant than silicon oxide. The high dielectric constant material may include, for example, one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide or lead zinc niobate.

Although the first gate insulating film 130 is shown as a single film, this example is only for convenience of explanation and the present disclosure is not limited thereto. The first gate insulating film 130 may include multiple films. The first gate insulating film 130 may include an interfacial layer between the first sheet pattern NS1 and the first gate electrode 120, and a high dielectric constant insulating film.

A semiconductor device according to some embodiments may include an NC (Negative Capacitance) FET that uses a negative capacitor. For example, the first gate insulating film 130 may include a ferroelectric material film having ferroelectric properties, and a paraelectric material film having paraelectric properties.

The ferroelectric material film may have a negative capacitance, and the paraelectric material film may have a positive capacitance. When two or more capacitors are connected in series and the capacitance of each capacitor has a positive value, the overall capacitances decrease from the capacitance of each of the individual capacitors. On the other hand, if at least one of the capacitances of two or more capacitors connected in series has a negative value, the overall capacitances may be greater than an absolute value of each of the individual capacitances, while having a positive value.

When the ferroelectric material film having the negative capacitance and the paraelectric material film having the positive capacitance are connected in series, the overall capacitance values of the ferroelectric material film and the paraelectric material film connected in series may increase. By the use of the increased overall capacitance value, a transistor including the ferroelectric material film may have a subthreshold swing (SS) below 60 mV/decade at room temperature.

The ferroelectric material film may have ferroelectric properties. The ferroelectric material film may include, for example, at least one of hafnium oxide, hafnium zirconium oxide, barium strontium titanium oxide, barium titanium oxide, and lead zirconium titanium oxide. Here, as an example, the hafnium zirconium oxide may be a material obtained by doping hafnium oxide with zirconium (Zr). As another example, the hafnium zirconium oxide may be a compound of hafnium (Hf), zirconium (Zr), and oxygen (O).

The ferroelectric material film may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). The type of dopant included in the ferroelectric material film may vary, depending on which type of ferroelectric material is included in the ferroelectric material film.

When the ferroelectric material film includes hafnium oxide, the dopant included in the ferroelectric material film may include, for example, at least one of gadolinium (Gd), silicon (Si), zirconium (Zr), aluminum (Al), and yttrium (Y).

When the dopant is aluminum (Al), the ferroelectric material film may include 3 to 8 at % (atomic %) aluminum. Here, a ratio of the dopant may be a ratio of aluminum to the sum of hafnium and aluminum.

When the dopant is silicon (Si), the ferroelectric material film may include 2 to 10 at % silicon. When the dopant is yttrium (Y), the ferroelectric material film may include 2 to 10 at % yttrium. When the dopant is gadolinium (Gd), the ferroelectric material film may include 1 to 7 at % gadolinium. When the dopant is zirconium (Zr), the ferroelectric material film may include 50 to 80 at % zirconium.

The paraelectric material film may have paraelectric properties. The paraelectric material film may include at least one of, for example, a silicon oxide and a metal oxide having a high dielectric constant. The metal oxide included in the paraelectric material film may include, for example, but is not limited to, at least one of hafnium oxide, zirconium oxide, and aluminum oxide.

The ferroelectric material film and the paraelectric material film may include the same material. The ferroelectric material film may have the ferroelectric properties, but the paraelectric material film may not have the ferroelectric properties. For example, when the ferroelectric material film and the paraelectric material film include hafnium oxide, a crystal structure of hafnium oxide included in the ferroelectric material film may differ from a crystal structure of hafnium oxide included in the paraelectric material film.

The ferroelectric material film may have a thickness having the ferroelectric properties. The thickness of the ferroelectric material film may be, for example, but not limited to, 0.5 to 10 nm. Since a critical thickness that exhibits the ferroelectric properties may vary for each ferroelectric material, the thickness of the ferroelectric material film may vary depending on the ferroelectric material.

As an example, the first gate insulating film 130 may include a single ferroelectric material film. As another example, the first gate insulating film 130 may include a plurality of ferroelectric material films spaced apart from each other. The first gate insulating film 130 may have a stacked film structure in which the plurality of ferroelectric material films and the plurality of paraelectric material films are alternately stacked.

The first gate spacer 140 may be on the side wall of the first gate electrode 120. The first gate spacers 140 may not be between the first lower pattern BP1 and the first sheet pattern NS1, and between the first sheet patterns NS1 adjacent in the third direction D3.

The first gate spacer 140 may include an inner side wall 140_ISW, a connecting side wall 140_CSW, and an outer side wall 140_OSW. The inner side wall 140_ISW of the first gate spacer may face the side wall of the first gate electrode 120 extending in the second direction D2. The inner side wall 140_ISW of the first gate spacers may extend in the second direction D2. The inner side wall 140_ISW of the first gate spacer may be a surface that is opposite to the outer side wall 140_OSW of the first gate spacer that faces a first interlayer insulating film 190. The connecting side wall 140_CSW of the first gate spacer may connect the inner side wall 140_ISW2 of the first gate spacer and the outer side wall 140_OSW of the first gate spacer. The connecting side wall 140_CSW of the first gate spacer may extend in the first direction D1.

The first gate insulating film 130 may extend along the inner side wall 140_ISW of the first gate spacer. The first gate insulating film 130 may be in contact with the inner side wall 140_ISW of the first gate spacer.

The first gate spacer 140 may include, for example, at least one of silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), and/or combinations thereof. Although the first gate spacer 140 is shown to be a single film, this example is only for convenience of explanation and the present disclosure is not limited thereto.

A first gate capping pattern 145 may be on the first gate electrode 120 and the first gate spacer 140. An upper surface of the first gate capping pattern 145 may be on the same plane as an upper surface of the first interlayer insulating film 190. In some embodiments, the first gate capping pattern 145 may be between the first gate spacers 140, in contrast to the shown example.

The first gate capping pattern 145 may include, for example, at least one of silicon nitride (SiN), silicon oxynitride (SiON), silicon carbonitride (SiCN), silicon oxycarbonitride (SiOCN), and/or combinations thereof. The first gate capping pattern 145 may include a material having an etch selectivity with respect to the interlayer insulating film 190.

A first source/drain pattern 150 may be formed on the first active pattern AP1. The first source/drain pattern 150 may be on the first lower pattern BP1. The first source/drain pattern 150 may be connected to the first sheet pattern NS1. The first source/drain pattern 150 may be in direct contact with the first sheet pattern NS1.

The first source/drain pattern 150 may be on the side surface of the first gate structure GS1. The first source/drain patterns 150 may be between the first gate structures GS1 adjacent to each other in the first direction D1. In some embodiments, the first source/drain patterns 150 may be on first and second sides of the first gate structure GS1. In some embodiments, and in contrast to the shown example, the first source/drain pattern 150 may be on one side of the first gate structure GS1 and not disposed on the other side of the first gate structure GS1.

The first source/drain pattern 150 may be included in a source/drain of a transistor that uses the first sheet pattern NS1 as a channel region.

The first source/drain pattern 150 may be in a first source/drain recess 150R. The first source/drain pattern 150 may fill the source/drain recess 150R.

The first source/drain recess 150R may extend in the third direction D3. The first source/drain recess 150R may be defined between the first gate structures GS1 adjacent to each other in the first direction D1.

A bottom surface of the first source/drain recess 150R may be defined by the first lower pattern BP1. The side walls of the first source/drain recess 150R may be defined by the first sheet pattern NS1 and the inner gate structures INT1_GS1, INT2_GS1 and INT3_GS1. The inner gate structures INT1_GS1, INT2_GS1 and INT3_GS1 may define parts or portions of side walls of the first source/drain recess 150R. In FIGS. 4 and 5, the first source/drain recess 150R includes the connecting side wall 140_CSW of the first gate spacer.

The inner gate structures INT1_GS1, INT2_GS1 and INT3_GS1 may include upper surfaces that face the lower surface NS1_BS of the first sheet pattern. The inner gate structures INT1_GS1, INT2_GS1 and INT3_GS1 include lower surfaces that face the upper surface NS1_US of the first sheet pattern or the upper surface BP1_US of the first lower pattern. The inner gate structures INT1_GS1, INT2_GS1 and INT3_GS1 include side walls that connect the upper surfaces of the inner gate structures INT1_GS1, INT2_GS1 and INT3_GS1 and the lower surfaces of the inner gate structures INT1_GS1, INT2_GS1 and INT3_GS1. The side walls of the inner gate structures INT1_GS1, INT2_GS1 and INT3_GS1 may define parts or portions of the side walls of the first source/drain recess 150R.

Between the first sheet pattern NS1 at the lowermost part and the first lower pattern BP1, a boundary between the first gate insulating film 130 and the first lower pattern BP1 may be an upper surface BP1_US of the first lower pattern. The upper surface BP1_US of the first lower pattern may be a boundary between the third inner gate structure INT3_GS1 and the first lower pattern BP1. A bottom surface of the first source/drain recess 150R may be lower than the upper surface BP1_US of the first lower pattern.

In FIG. 2, side walls of the first source/drain recess 150R may have a wavy or undulating shape. The first source/drain recess 150R may include a plurality of width extension regions 150R_ER. Each of the width extension region 150R_ER of first source/drain recess may be defined above the upper surface BP1_US of the first lower pattern.

Width extension regions 150R_ER of the first source/drain recess 150R may be defined between a pair of the first sheet patterns NS1 that are adjacent in the third direction D3. A width extension region 150R_ER of the first source/drain recess may also be defined between the first lower pattern BP1 and the first sheet pattern NS1. The width extension region 150R_ER of the first source/drain recess 150R may extend between a pair of the first sheet patterns NS1 adjacent in the third direction D3. The width extension region 150R_ER of the first source/drain recess may be defined between the inner gate structures INT1_GS1, INT2_GS1 and INT3_GS1 adjacent in the first direction D1.

Each of the width extension region 150R_ER of the first source/drain recess 150R may include a portion whose width in the first direction D1 increases and a portion whose width in the first direction D1 decreases, as a distance in the third direction D3 increases from the upper surface BP1_US of the first lower pattern BP1. For example, the width of the width extension region 150R_ER of the first source/drain recess may increase and then decrease, as a distance in the third direction D3 increases from the upper surface BP1_US of the first lower pattern BP1.

In the semiconductor device according to some embodiments, a point on which the width extension region 150R_ER of the first source/drain recess 150 has a maximum width that is located between (e.g., equidistant from) the first sheet pattern NS1 and the first lower pattern BP1, or between (e.g., equidistant from) the pair of first sheet patterns NS1 adjacent in the third direction D3.

The first source/drain pattern 150 may be in direct contact with the first sheet pattern NS1 and the first lower pattern BP1. A part of the first source/drain pattern 150 may be in contact with the connecting side wall 140_CSW of the first gate spacer. The first gate insulating films 130 of the inner gate structures INT1_GS1, INT2_GS1 and INT3_GS1 may be in contact with the first source/drain pattern 150.

The first source/drain pattern 150 may include a semiconductor liner film 151, a semiconductor insertion film 152, and a semiconductor filling film 153.

The semiconductor liner film 151 may be formed (e.g., continuously formed) along the first source/drain recess 150R. The semiconductor liner film 151 may extend along the side walls of the first source/drain recess 150R and the bottom surface of the first source/drain recess 150R. The semiconductor liner film 151 formed along the first source/drain recess 150R defined by the first sheet pattern NS1 may be directly connected to the semiconductor liner film 151 formed along the first source/drain recess 150R defined by the inner gate structures INT1_GS1, INT2_GS1 and INT3_GS1.

The semiconductor liner film 151 may be in contact with the first sheet pattern NS1, the first lower pattern BP1, and the inner gate structures INT1_GS1, INT2_GS1 and INT3_GS1. The semiconductor liner film 151 may be in contact with the first gate insulating films 130 of the inner gate structures INT1_GS1, INT2_GS1 and INT3_GS1.

The semiconductor liner film 151 may include an outer surface 151_OSW and an inner surface 151_ISW. The outer surface 151_OSW of the semiconductor liner film 151 may be in contact with the first gate insulating film 130, the first sheet pattern NS1 and the first lower pattern BP1. The outer surface 151_OSW of the semiconductor liner film 151 may be in contact with the side walls of the inner gate structures INT1_GS1, INT2_GS1, INT3_GS1. The outer surface 151_OSW of the semiconductor liner film may show the profile of the first source/drain recess 150R.

The inner surface 151_ISW of the semiconductor liner film 151 may be a surface that is opposite to the outer surface 151_OSW of the semiconductor liner film 151. The inner surface 151_ISW of the semiconductor liner film 151 may be a surface which faces the semiconductor filling film 153.

The semiconductor liner film 151 may cover a part of the connecting side walls 140_CSW of the first gate spacer 140. The semiconductor liner film 151 may protrude in the first direction D1 from the outer side wall 140_OSW of the first gate spacer 140 at the portion which is in contact with the first sheet pattern NS1. In the portion which is in contact with the first sheet pattern NS1, the inner surface 151_ISW of the semiconductor liner film 151 may protrude in the first direction D1 from the outer side wall 140_OSW of the first gate spacer 140.

The semiconductor liner film 151 may define a liner recess 151R. For example, the liner recess 151R may be defined by the inner surface 151_ISW of the semiconductor liner film. The side wall of the liner recess 151R may have a wavy or undulating shape. In FIGS. 2 and 6, the side wall of the liner recess 151R may be a portion of the liner recess 151R located above a reference line F1 of FIG. 6. For example, a position of the reference line F1 of FIG. 6 may be a position corresponding to the upper surface BP1_US of the first lower pattern of FIG. 2.

The liner recess 151R may include multiple width extension regions 151R_ER. Each of the width extension regions 151R_ER of the liner recess 151R may be defined above the upper surface BP1_US of the first lower pattern BP1. In the semiconductor device according to some embodiments, the width extension region 151R_ER of the liner recess 151R may be defined at a position corresponding to the width extension region 150R_ER of the first source/drain recess 150R.

The width extension region 151R_ER of the liner recess 151R may be defined between a pair of the first sheet patterns NS1 that are adjacent in the third direction D3. The width extension region 151R_ER of the liner recess 151R may be defined between the first lower pattern BP1 and the first sheet pattern NS1. The width extension region 151R_ER of the liner recess 151R may be defined between the inner gate structures INT1_GS1, INT2_GS1, and INT3_GS1 adjacent to each other in the first direction D1.

Each of the width extension region 151R_ER of the liner recess 151R may include a portion whose width in the first direction D1 increases and a portion whose width in the first direction D1 decreases, as a distance in the third direction D3 increases from the upper surface BP1_US of the first lower pattern BP1. For example, the width of the width extension region 150R_ER of the liner recess may increase and then decrease, as it moves away from the upper surface BP1_US of the first lower pattern.

In each of the width extension regions 151R_ER of the liner recess 151, a point on which the width extension region 151R_ER of the liner recess 151 has the maximum width may be located between (e.g., equidistant from) the first sheet pattern NS1 and the first lower pattern BP1, or between a pair of the first sheet patterns NS1 that are adjacent in the third direction D3.

In some embodiments, and as seen in FIG. 7, the semiconductor liner film 151 may be in contact with the entire side walls of the second inner gate structure INT2_GS1. Although not shown, the semiconductor liner film 151 may also be in contact with the entire side walls of the first inner gate structure INT1_GS1 and the entire side walls of the third inner gate structure INT3_GS1.

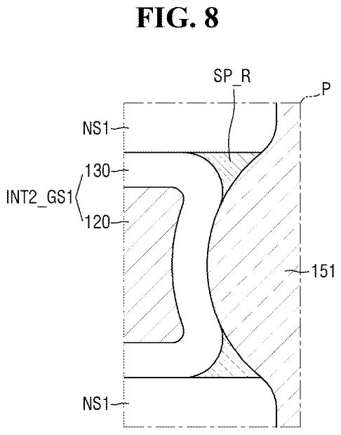

In some embodiments, and as seen in FIG. 8, a semiconductor residue pattern SP_R may be between the second inner gate structure INT2_GS1 and the semiconductor liner film 151. The semiconductor residue pattern SP_R may be in contact with the first sheet pattern NS1. The semiconductor residue pattern SP_R may be in contact with the outer surface 151_OSW of the semiconductor liner film and side walls of the second inner gate structure INT2_GS1.

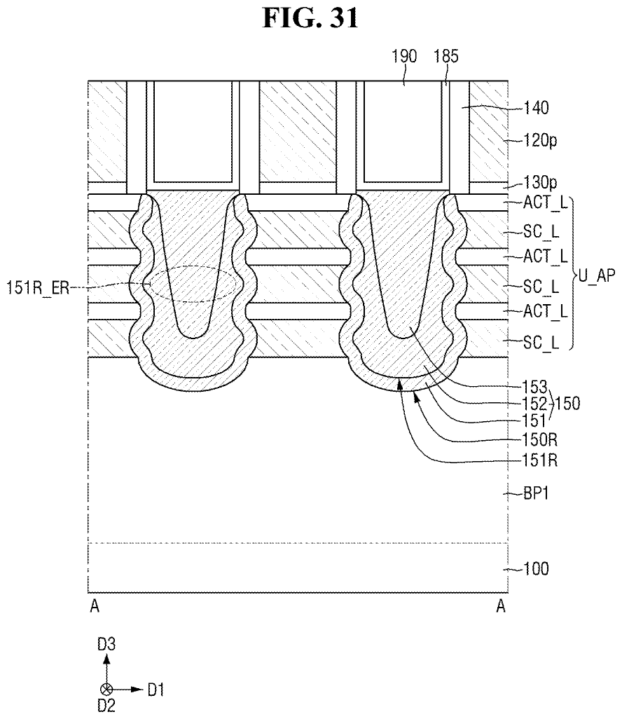

The semiconductor residue pattern SP_R may include, for example, silicon-germanium. When the semiconductor liner film 151 includes silicon-germanium, the germanium fraction of the semiconductor residue pattern SP_R is greater than the germanium fraction of the semiconductor liner film 151. The semiconductor residue pattern SP_R may remain after the sacrificial pattern (SC_L of FIG. 31) is removed.

Although not shown, the semiconductor residue pattern SP_R may also be between the first inner gate structure INT1_GS1 and the semiconductor liner film 151, or between the third inner gate structure INT3_GS1 and the semiconductor liner film 151.

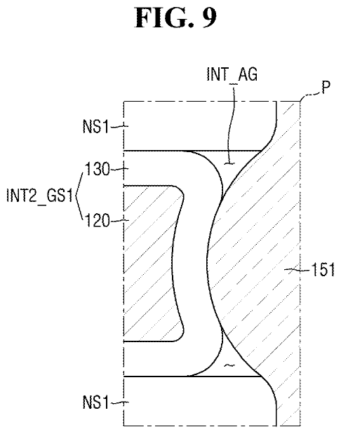

In some embodiments, and as seen in FIG. 9, an inner gate air gap INT_AG may be between the second inner gate structure INT2_GS1 and the semiconductor liner film 151. The inner gate air gap INT_AG may be between the semiconductor liner film 151 and the first gate insulating film 130 of the second inner gate structure INT2_GS1. The inner gate air gap INT_AG may be defined between the semiconductor liner film 151, the first sheet pattern NS1 and the second inner gate structure INT2_GS1.

Although not shown, when the first gate insulating film 130 includes an interfacial layer and a high dielectric constant insulating film, the interfacial layer may be formed on the semiconductor liner film 151 that is in contact with the inner gate air gap INT_AG.

In addition, although not shown, the inner gate air gap INT_AG may also be between the first inner gate structure INT1_GS1 and the semiconductor liner film 151, or between the third inner gate structure INT3_GS1 and the semiconductor liner film 151.

The semiconductor insertion film 152 and the semiconductor filling film 153 may be inside the liner recess 151R. The semiconductor insertion film 152 and the semiconductor filling film 153 may fill portions of the liner recess 151R.

The semiconductor insertion film 152 may be on the semiconductor liner film 151. The semiconductor insertion film 152 may be formed along the liner recess 151R. The semiconductor insertion film 152 may be in contact with the semiconductor liner film 151. The semiconductor insertion film 152 is in contact with the inner surface 151_ISW of the semiconductor liner film 151.

In the semiconductor device according to some embodiments, the semiconductor insertion film 152 may be formed (e.g., continuously formed) along the inner surface 151_ISW of the semiconductor liner film. For example, the semiconductor insertion film 152 may cover the entire inner surface 151_ISW of the semiconductor liner film. The entire inner surface 151_ISW of the semiconductor liner film may be in contact with the semiconductor insertion film 152.

The semiconductor insertion film 152 may include an outer surface 152_OSW and an inner surface 152_ISW. The outer surface 152_OSW of the semiconductor insertion film 152 may be in contact with the semiconductor liner film 151. The outer surface 152_OSW of the semiconductor insertion film 152 may be in contact with the inner surface 151_ISW of the semiconductor liner film 151.

The semiconductor liner film 151 may be formed along the outer surface 152_OSW of the semiconductor insertion film 152. For example, the semiconductor liner film 151 may be in contact with the entire outer surface 152_OSW of the semiconductor insertion film.

The outer surface 152_OSW of the semiconductor insertion film 152 may face the first sheet pattern NS1 and the inner gate structures INT1_GS1, INT2_GS1 and INT3_GS1. Since the semiconductor liner film 151 may be between the semiconductor insertion film 152 and the first sheet pattern NS1, the outer surface 152_OSW of the semiconductor insertion film 152 may not be in contact with the first sheet pattern NS1. Also, the outer surface 152_OSW of the semiconductor insertion film 152 may not be in contact with the inner gate structures INT1_GS1, INT2_GS1, and INT3_GS1.

The inner surface 152_ISW of the semiconductor insertion film may be a surface that is opposite to the outer surface 152_OSW of the semiconductor insertion film. The inner surface 152_ISW of the semiconductor insertion film may be a surface that faces the semiconductor filling film 153.

The inner surface 152_ISW of the semiconductor insertion film 152 may define a filling film recess. A width of the filling film recess in the first direction D1 may increase, as a distance in the third direction D3 increases from the first lower pattern BP1.

The semiconductor filling film 153 may be on the semiconductor liner film 151 and the semiconductor insertion film 152. The semiconductor insertion film 152 may be between the semiconductor filling film 153 and the semiconductor liner film 151. The semiconductor filling film 153 may fill a filling film recess defined by the inner surface 152_ISW of the semiconductor insertion film.

The semiconductor filling film 153 may be in contact with the semiconductor insertion film 152. The semiconductor filling film 153 may be in contact with the inner surface 152_ISW of the semiconductor insertion film 152. In the semiconductor device according to some embodiments, the width of the semiconductor filling film 153 in the first direction D1 may increase, as a distance in the third direction D3 increases from the first lower pattern BP1.

When the semiconductor insertion film 152 covers the entire inner surface 151_ISW of the semiconductor liner film 151, the semiconductor filling film 153 may not be in contact with the semiconductor liner film 151. In the semiconductor device according to some embodiments, the semiconductor filling film 153 may not be in contact with the inner surface 151_ISW of the semiconductor liner film 151.

The semiconductor liner film 151, the semiconductor insertion film 152, and the semiconductor filling film 153 may each include silicon-germanium. The semiconductor liner film 151, the semiconductor insertion film 152, and the semiconductor filling film 153 may each include a silicon-germanium film. The semiconductor liner film 151, the semiconductor insertion film 152, and the semiconductor filling film 153 may each be an epitaxial semiconductor film.

The semiconductor liner film 151, the semiconductor insertion film 152, and the semiconductor filling film 153 may each include doped p-type impurities. For example, the p-type impurity may be, but not limited to, boron (B).

As seen in FIG. 10, the germanium fraction of the semiconductor insertion film 152 may be greater than the germanium fraction of the semiconductor liner film 151. The germanium fraction of the semiconductor insertion film 152 may be smaller than the germanium fraction of the semiconductor filling film 153.

The shape of the semiconductor liner film 151 and the shape of the semiconductor insertion film 152 will be further described using FIGS. 2 and 6.

The inner surface 151_ISW of the semiconductor liner film 151 may include a plurality of first inner convex curved regions 151_ICVR and a plurality of first inner concave curved regions 151_ICCR.

The plurality of first inner concave curved regions 151_ICCR may be in the width extension region 151R_ER of the liner recess 151R. The plurality of first inner concave curved regions 151_ICCR may be located at points that overlap or are aligned in the first direction D1 with the gate electrodes 120 of the inner gate structures INT1_GS1, INT2_GS1 and INT3_GS1.

The plurality of first inner convex curved regions 151_ICVR may be between the width extension regions 151R_ER of the liner recess 151 that are adjacent in the third direction D3. For example, the plurality of first inner convex curved regions 151_ICVR may be located at points that overlap or are aligned in the first direction D1 with the first sheet patterns NS1.

A first inner convex curved region 151_ICVR may be located between the first inner concave curved regions 151_ICCR adjacent to each other in the third direction D3. The first inner concave curved region 151_ICCR may be located between the first inner convex curved regions 151_ICVR adjacent to each other in the third direction D3.

The plurality of first inner convex curved regions 151_ICVR and the plurality of first inner concave curved regions 151_ICCR may be above the reference line F1.

The outer surface 151_OSW of the semiconductor liner film may include a plurality of first outer convex curved regions 151_OCVR and a plurality of first outer concave curved regions 151_OCCR.

For example, the first outer convex curved region 151_OCVR may be at a position corresponding to the first inner concave curved region 151_ICCR. The first outer concave curved region 151_OCCR may be at a position corresponding to the first inner convex curved region 151_ICVR.

The first outer convex curved regions 151_OCVR may be in contact with the first gate insulating film 130 of the inner gate structures INT1_GS1, INT2_GS1, and INT3_GS1. The first outer concave curved regions 151_OCCR may be in contact with the first sheet pattern NS1. The first outer concave curved regions 151_OCCR may, for example, be in contact with a terminating end of the first sheet pattern NS1. In a cross-sectional view as in FIG. 2, the first sheet pattern NS1 may include two terminating ends spaced apart in the first direction D1.

The plurality of first outer convex curved regions 151_OCVR and the plurality of first outer concave curved regions 151_OCCR may be above the reference line F1.

The outer surface 152_OSW of the semiconductor insertion film 152 may include a plurality of second outer convex curved regions 152_OCVR and a plurality of second outer concave curved regions 152_OCCR.

For example, the second outer convex curved region 152_OCVR may be at a position corresponding to the first inner concave curved region 151_ICCR. Since the second outer convex curved region 152_OCVR and the first inner concave curved region 151_ICCR are the boundaries between the semiconductor liner film 151 and the semiconductor insertion film 152, the second outer convex curved regions 152_OCVR may be located at the same position as the first inner concave curved regions 151_ICCR. For example, the second outer concave curved region 152_OCCR may be at a position corresponding to the first inner convex curved region 151_ICVR.

The plurality of second outer convex curved regions 152_OCVR and the plurality of second outer concave curved regions 152_OCCR may be above the reference line F1.

In the semiconductor device according to some embodiments, the inner surface 152_ISW of the semiconductor insertion film 152 may not include a convex curved region and a concave curved region which are alternately disposed.

The source/drain etch stop film 185 may extend along the outer side wall 140_OSW of the first gate spacer and the profile of the first source/drain pattern 150. Although not shown, the source/drain etch stop film 185 may be on the upper surface of the field insulating film 105.

The source/drain etch stop film 185 may include a material having an etch selectivity with respect to the first interlayer insulating film 190, which will be described in greater detail below. The source/drain etch stop film 185 may include, for example, at least one of silicon nitride (SiN), silicon oxynitride (SiON), silicon oxycarbonitride (SiOCN), silicon boronitride (SiBN), silicon oxyboronitride (SiOBN), silicon oxycarbide (SiOC), and/or combinations thereof.

The first interlayer insulating film 190 may be on the source/drain etch stop film 185. The first interlayer insulating film 190 may be on the first source/drain pattern 150. The first interlayer insulating film 190 may not cover the upper surface of the first gate capping pattern 145. For example, the upper surface of the first interlayer insulating film 190 may be on the same plane as the upper surface of the first gate capping pattern 145, or stated differently each is at a same distance from the upper surface BP1_US of the first lower pattern BP1.

The first interlayer insulating film 190 may include, for example, at least one of silicon oxide, silicon nitride, silicon oxynitride and a low dielectric constant material. Examples of the low dielectric constant material may include, but are not limited to, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped silicon Oxide), OSG (Organo Silicate Glass), SiLK, Amorphous Fluorinated Carbon, silica aerogels, silica xerogels, mesoporous silica and/or combinations thereof.

The first source/drain contact 180 may be on the first source/drain pattern 150. The first source/drain contact 180 may be connected to the first source/drain pattern 150. The first source/drain contact 180 may pass through the first interlayer insulating film 190 and the source/drain etch stop film 185, and may be connected to the first source/drain pattern 150.

A first contact silicide film 155 may be between the first source/drain contact 180 and the first source/drain pattern 150.

Although the first source/drain contact 180 is shown to be a single film, the example is only for convenience of explanation and the present disclosure is not limited thereto. The first source/drain contact 180 may include, for example, at least one of a metal, a metal alloy, conductive metal nitride, conductive metal carbide, conductive metal oxide, conductive metal carbonitride, and/or a two-dimensional (2D) material.

The first contact silicide film 155 may include a metal silicide material.

A second interlayer insulating film 191 may be on the first interlayer insulating film 190. The second interlayer insulating film 191 may include, for example, at least one of silicon oxide, silicon nitride, silicon oxynitride, and/or a low dielectric constant material.

The wiring structure 205 may be inside the second interlayer insulating film 191. The wiring structure 205 may be connected with the first source/drain contact 180. The wiring structure 205 may include a wiring line 207 and a wiring via 206.

Although the wiring line 207 and the wiring via 206 are shown to be distinguished from each other, this example is only for convenience of explanation, and the present disclosure is not limited thereto. That is, in some embodiments, the wiring line 207 may be formed after the wiring via 206 is formed. As another example, the wiring via 206 and the wiring line 207 may be formed at the same time.

Although the wiring line 207 and the wiring via 206 are each shown as a single film, this example is only for convenience of explanation and the present disclosure is not limited thereto. The wiring line 207 and the wiring via 206 may each include, for example, at least one of a metal, a metal alloy, conductive metal nitride, conductive metal carbide, conductive metal oxide, conductive metal carbonitride, and/or a two-dimensional (2D) material.

In some embodiments, the upper surface of the first source/drain contact 180 of the portion connected to the wiring structure 205 may be on the same plane as the upper surface of the first source/drain contact 180 of the portion not connected to the wiring structure 205, or stated differently each is at a same distance from the upper surface BP1_US of the first lower pattern BP1.

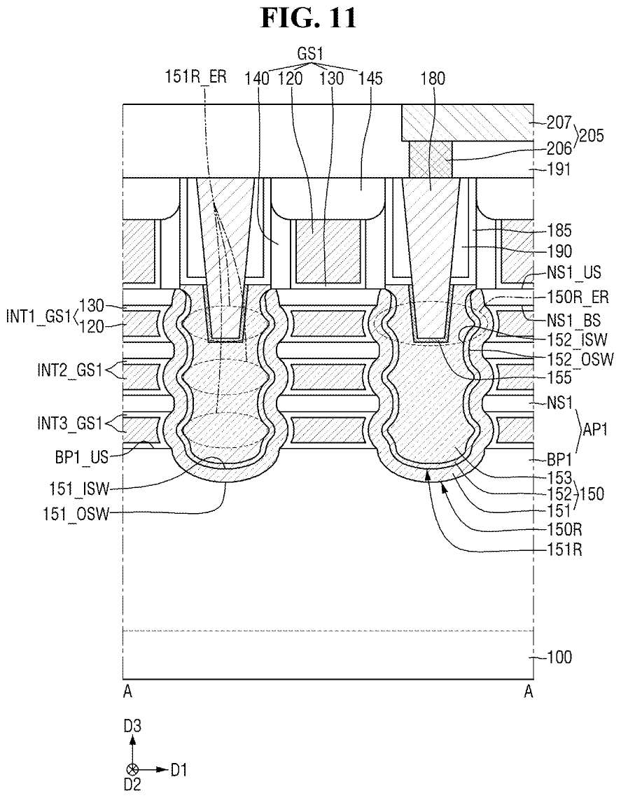

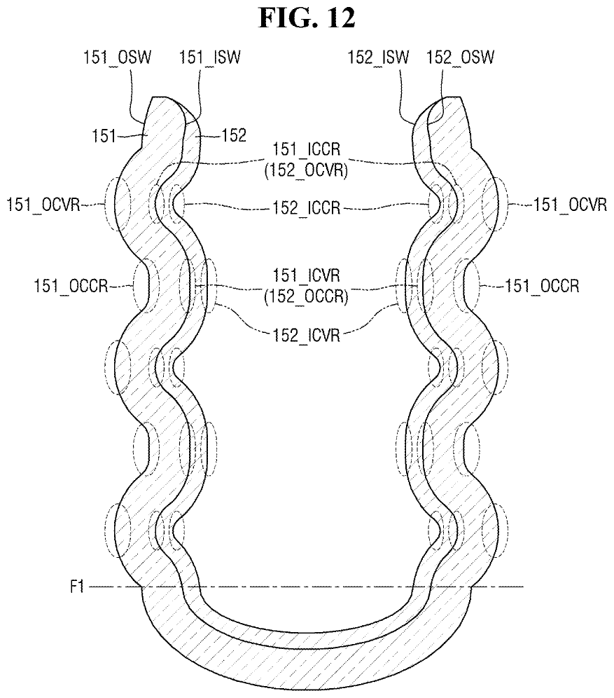

FIGS. 11 and 12 are diagrams for explaining a semiconductor device according to some embodiments. For convenience of explanation, the explanation will be provided mainly on points that are different from those explained using FIGS. 1 to 10.

For reference, FIG. 12 is a diagram for explaining the shapes of the semiconductor liner film and the semiconductor insertion film of FIG. 11.

Referring to FIGS. 11 and 12, in the semiconductor device according to some embodiments, the semiconductor insertion film 152 may be formed with wavy or undulating outer and inner surfaces along the inner surface 151_ISW of the semiconductor liner film.

The filling film recess defined by the inner surface 152_ISW of the semiconductor insertion film may include a width extension region, which may be similar to the liner recess 151R.

The semiconductor filling film 153 may include at least one or more bulge portions. In the bulge portions of the semiconductor filling film 153, the width of the semiconductor filling film 153 in the first direction D1 may increase and then decrease, as a distance in the third direction D3 increases from the first lower pattern BP1.

The inner surface 152_ISW of the semiconductor insertion film 152 may include a plurality of second inner convex curved regions 152_ICVR and a plurality of second inner concave curved regions 152_ICCR.

For example, the second outer convex curved region 152_OCVR may be provided at a position corresponding to the second inner concave curved region 152_ICCR. The second outer concave curved region 152_OCCR may be provided at a position corresponding to the second inner convex curved region 152_ICVR.

The plurality of second outer convex curved regions 152_OCVR and the plurality of second outer concave curved regions 152_OCCR may be above the reference line F1.

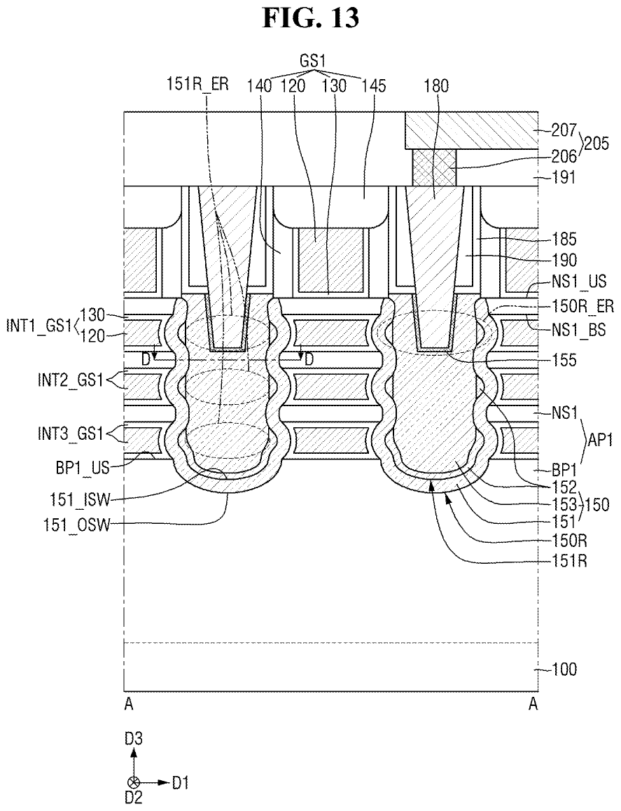

FIGS. 13 to 15 are diagrams for explaining a semiconductor device according to some embodiments. For convenience of explanation, the explanation will be provided mainly on points that are different from those explained using FIGS. 1 to 10.

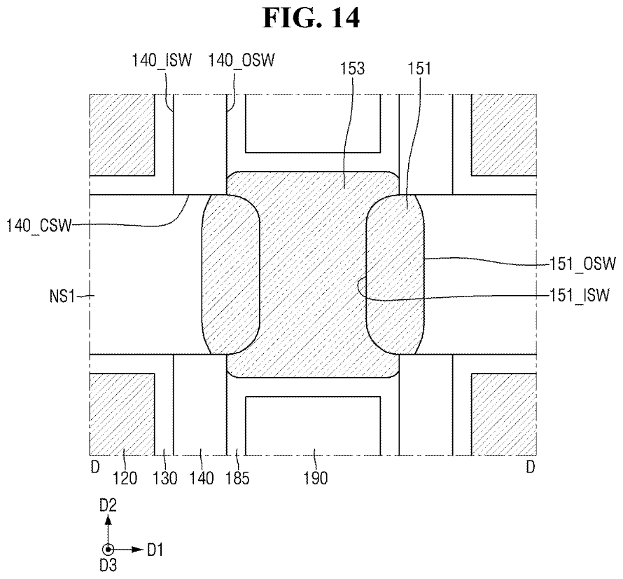

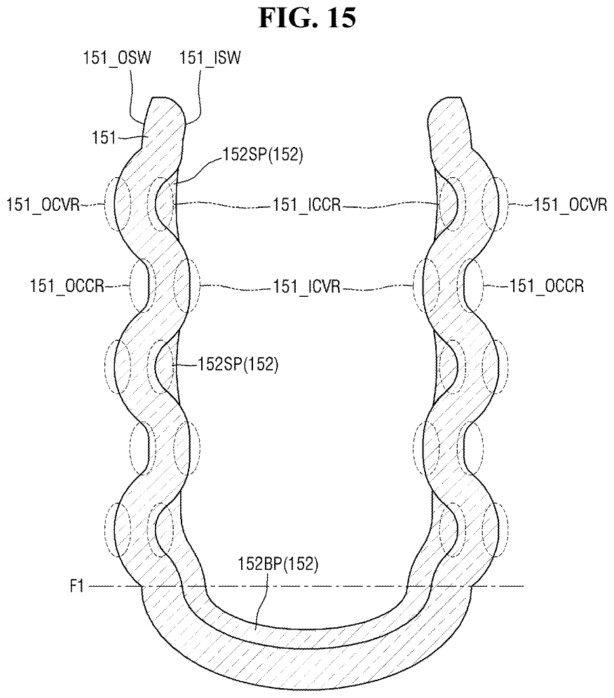

For reference, FIG. 14 is a plan view taken along line D-D of FIG. 13 and viewed from above. FIG. 15 is a diagram for explaining the shapes of the semiconductor liner film and the semiconductor insertion film of FIG. 13.

Referring to FIGS. 13 and 14, in the semiconductor device according to some embodiments, the first source/drain pattern 150 may include a plurality of semiconductor insertion films 152 that are spaced apart from each other in the third direction D3.

Each semiconductor insertion film 152 may be between the semiconductor liner film 151 and the semiconductor filling film 153. Each semiconductor insertion film 152 may be in contact with the semiconductor liner film 151 and the semiconductor filling film 153.

The semiconductor insertion film 152 may include a first sub-semiconductor insertion film 152BP and a second sub-semiconductor insertion film 152SP. The first sub-semiconductor insertion film 152BP may be spaced apart from the second sub-semiconductor insertion film 152SP. The first sub-semiconductor insertion film 152BP may be spaced apart from the second sub-semiconductor insertion film 152SP in the third direction D3. The first sub-semiconductor insertion film 152BP may be separated from and not in contact with the second sub-semiconductor insertion film 152SP.

The first sub-semiconductor insertion film 152BP may be formed along a bottom surface of the liner recess 151R. The first sub-semiconductor insertion film 152BP may fill a portion of the first inner concave curved region 151_ICCR at the lowermost part thereof.

The second sub-semiconductor insertion film 152SP may be on the side wall of the liner recess 151R. The second sub-semiconductor insertion film 152SP may be in the first inner concave curved region 151_ICCR and may fill a portion of the first inner concave curved region 151_ICCR.

At least some of the plurality of semiconductor insertion films 152 may be in the first inner concave curved region 151_ICCR.

The second sub-semiconductor insertion film 152SP may not entirely cover the first inner convex curved region 151_ICVR. In FIG. 14, the semiconductor insertion film 152 may not cover the inner surface 151_ISW of the semiconductor liner at the portion that is in contact with the first sheet pattern NS1. The semiconductor insertion film 152 may not be between the semiconductor liner film 151 and the semiconductor filling film 153 in the portion that is in contact with the first sheet pattern NS1.

The semiconductor liner film 151 that defines the first inner convex curved region 151_ICVR may be between the second sub-semiconductor insertion films 152SP adjacent to each other in the third direction D3. The second sub-semiconductor insertion films 152SP adjacent to each other in the third direction D3 may not be in contact with each other. The semiconductor liner film 151 that defines the first inner convex curved region 151_ICVR may be between the first sub-semiconductor insertion film 152BP and the second sub-semiconductor insertion film 152SP.

Since the entire inner surface 151_ISW of the semiconductor liner film is not in contact with the semiconductor insertion film 152, the semiconductor liner film 151 may be in contact with the semiconductor filling film 153. A part of the inner surface 151_ISW of the semiconductor liner film 151 may be in contact with the semiconductor insertion film 152, and the rest of the inner surface 151_ISW of the semiconductor liner film may be in contact with the semiconductor filling film 153.

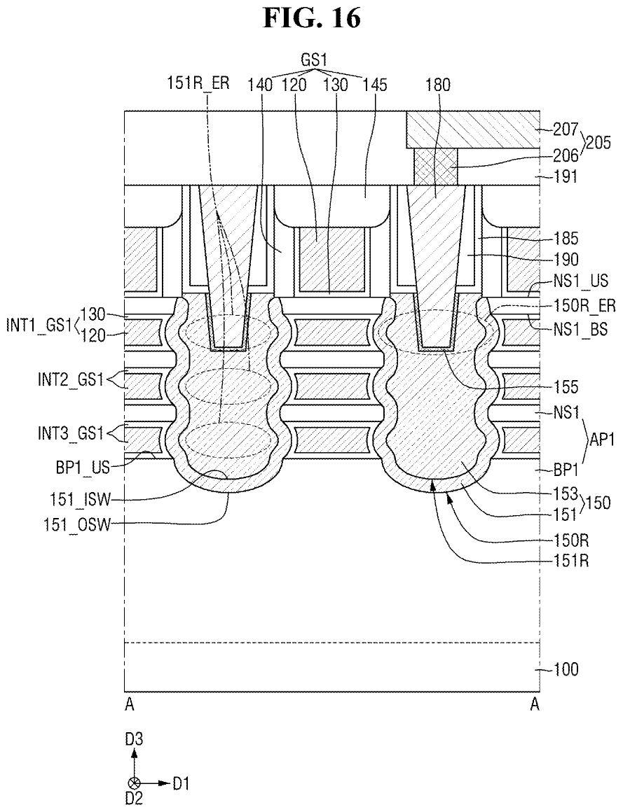

FIG. 16 is a diagram for explaining a semiconductor device according to some embodiments. For convenience of explanation, the explanation will be provided mainly on points that are different from those explained using FIGS. 1 to 10.

Referring to FIG. 16, in a semiconductor device according to some embodiments, a first source/drain pattern 150 includes a semiconductor liner film 151 and a semiconductor filling film 153. Stated differently, in some embodiments a semiconductor insertion film 152 may be optional and therefore omitted.

The entire inner surface 151_ISW of the semiconductor liner film 151 may be in contact with the semiconductor filling film 153.

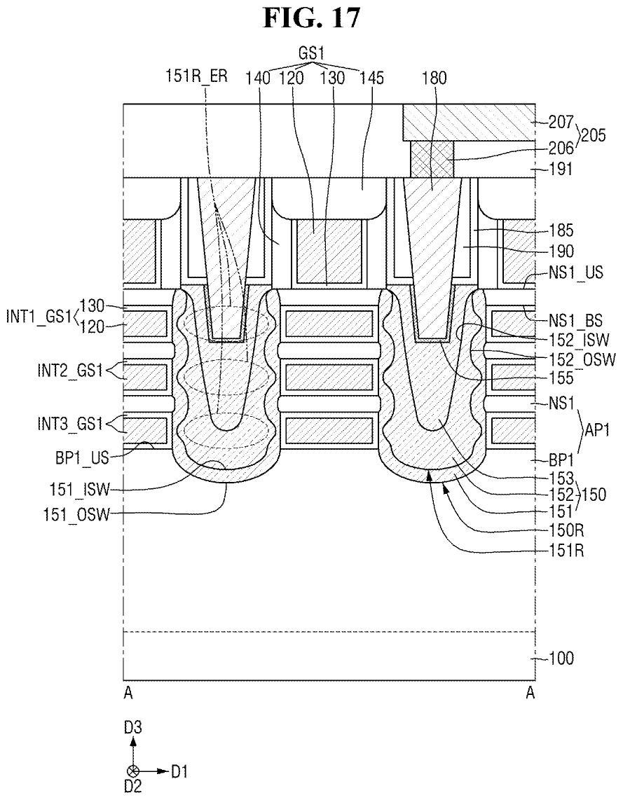

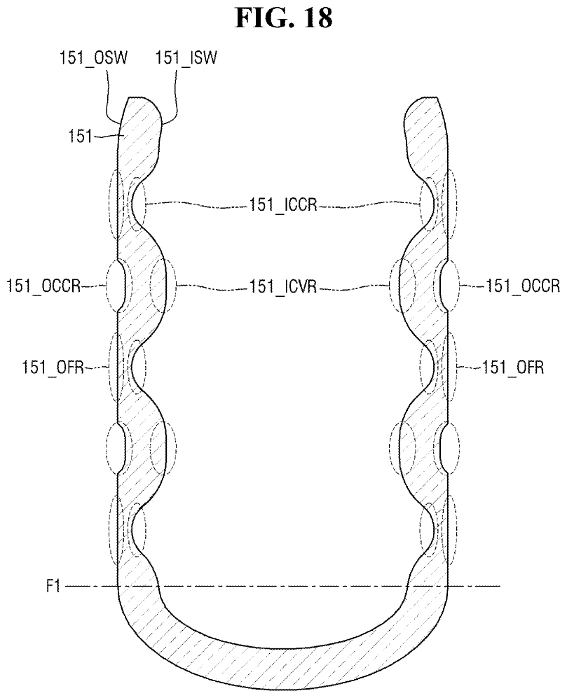

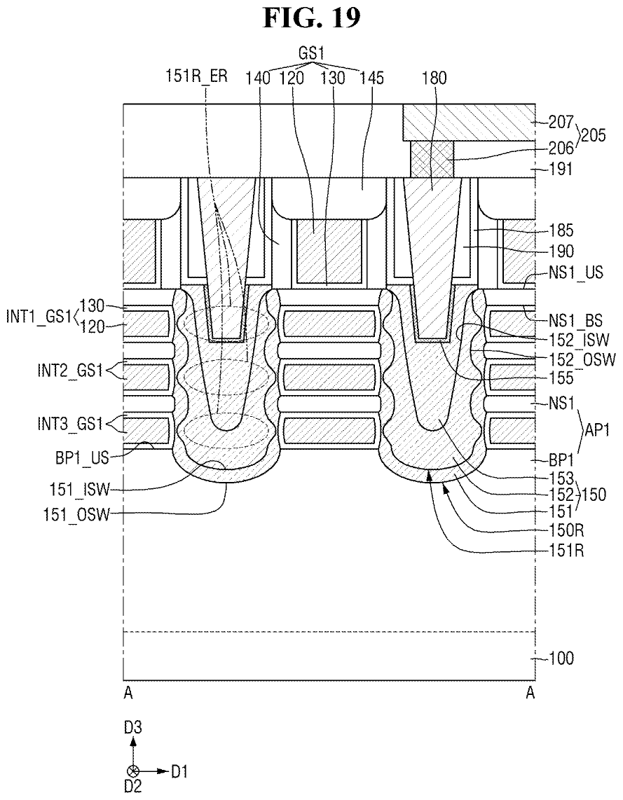

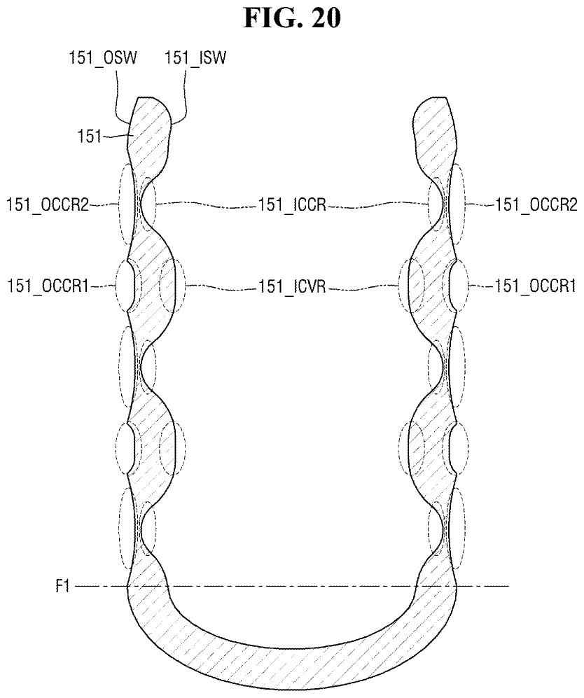

FIGS. 17 and 18 are diagrams for explaining a semiconductor device according to some embodiments. FIGS. 19 and 20 are diagrams for explaining the semiconductor device according to some embodiments. For convenience of explanation, the explanation will be provided mainly on points that are different from those explained using FIGS. 1 to 10.

For reference, FIG. 18 is a diagram for explaining the shape of the semiconductor liner film 151 of FIG. 17. FIG. 20 is a diagram for explaining the shape of the semiconductor liner film 151 of FIG. 19.

Referring to FIGS. 17 and 18, in the semiconductor device according to some embodiments, the outer surface 151_OSW of the semiconductor liner film 151 may include a plurality of first outer planar regions 151_OFR and a plurality of first outer concave curved regions 151_OCCR.

The first outer planar region 151_OFR may be at a position that corresponds to the first inner concave curved region 151_ICCR. The first outer planar region 151_OFR may be in contact with the first gate insulating films 130 of the inner gate structures INT1_GS1, INT2_GS1, and INT3_GS1.

The first outer concave curved region 151_OCCR may be located between the first outer planar regions 151_OFR that are adjacent to each other in the third direction D3. The first outer planar region 151_OFR may be located between the first outer concave curved regions 151_OCCR that are adjacent to each other in the third direction D3.

The first outer planar region 151_OFR and the plurality of first outer concave curved regions 151_OCCR may be above the reference line F1.

Referring to FIGS. 19 and 20, in the semiconductor device according to some embodiments, the outer surface 151_OSW of the semiconductor liner film 151 may include a plurality of first sub-concave curved regions 151_OCCR1 and a plurality of second sub-concave curved regions 151_OCCR2.

For example, the first sub-concave curved region 151_OCCR1 may be at a position that corresponds to the first inner convex curved region 151_ICVR. The second sub-concave curved region 151_OCCR2 may be disposed at a position corresponding to the first inner concave curved region 151_ICCR.

The first sub-concave curved region 151_OCCR1 may be in contact with the first sheet pattern NS1. For example, the first sub-concave curved region 151_OCCR1 may be in contact with the end of the first sheet pattern NS1.

The second sub-concave curved region 151_OCCR2 may be in contact with the first gate insulating film 130 of the inner gate structures INT1_GS1, INT2_GS1, and INT3_GS1.

The plurality of first sub-concave curved regions 151_OCCR1 and the plurality of second sub-concave curved regions 151_OCCR2 may be above the reference line F1.

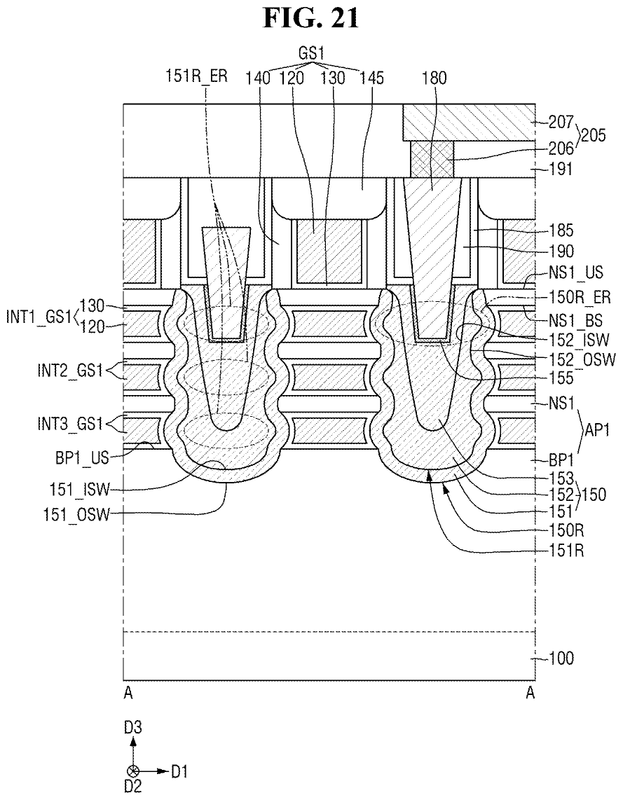

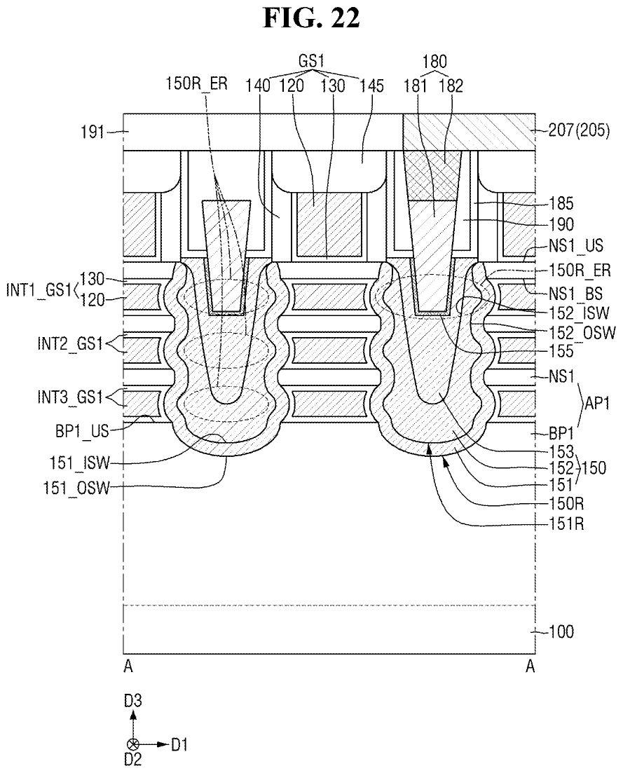

FIGS. 21 and 22 are diagrams for explaining a semiconductor device according to some embodiments, respectively. For convenience of explanation, the explanation will be provided mainly on points that are different from those explained using FIGS. 1 to 10.

Referring to FIG. 21, in the semiconductor device according to some embodiments, the upper surface of the first source/drain contact 180 of the portion not connected to the wiring structure 205 may be lower than the upper surface of the first gate capping pattern 145. Stated differently, the upper surface of the first source/drain contact 180 of the portion not connected to the wiring structure 205 may be closer to the substrate 100 than the upper surface of the first gate capping pattern 145 is to the substrate 100.

The upper surface of the first source/drain contact 180 of the portion connected to the wiring structure 205 may be higher than the upper surface of the first source/drain contact 180 of the portion not connected to the wiring structure 205. Stated differently, the upper surface of the first source/drain contact 180 of the portion connected to the wiring structure 205 may be farther to the substrate 100 than the upper surface of the first source/drain contact 180 of the portion not connected to the wiring structure 205 is to the substrate 100.

Referring to FIG. 22, in the semiconductor device according to some embodiments, the first source/drain contact 180 includes a lower source/drain contact 181 and an upper source/drain contact 182.

The upper source/drain contact 182 may be in the portion connected to the wiring structure 205. On the other hand, the upper source/drain contacts 182 may not be in the portion not connected to the wiring structure 205.

The wiring line 207 may be connected to the first source/drain contact 180 without a wiring via (206 of FIG. 2). The wiring structure 205 may not include the wiring via (206 of FIG. 2).

Although the lower source/drain contact 181 and the upper source/drain contact 182 are each shown as a single film, the example is only for convenience of explanation and the present disclosure is not limited thereto. The lower source/drain contact 181 and the upper source/drain contact 182 may each include, for example, at least one of metal, metal alloy, conductive metal nitride, conductive metal carbide, conductive metal oxide, conductive metal carbonitride, and two-dimensional materials.

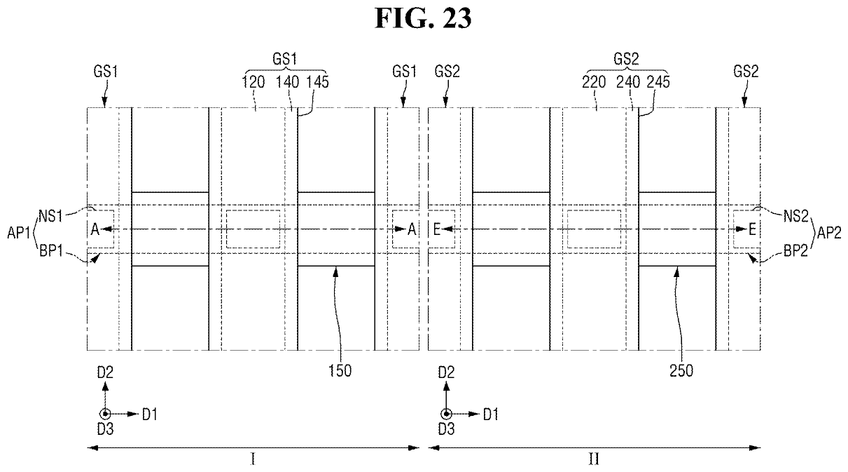

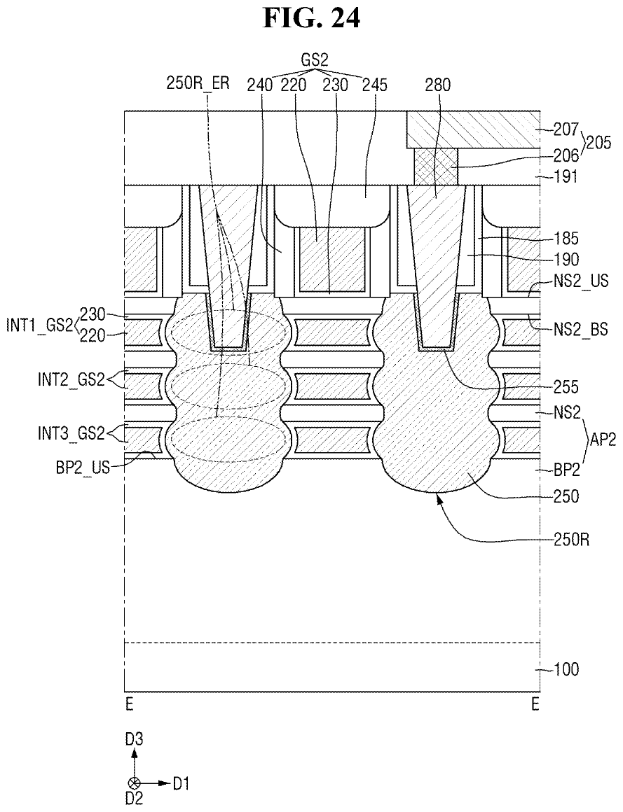

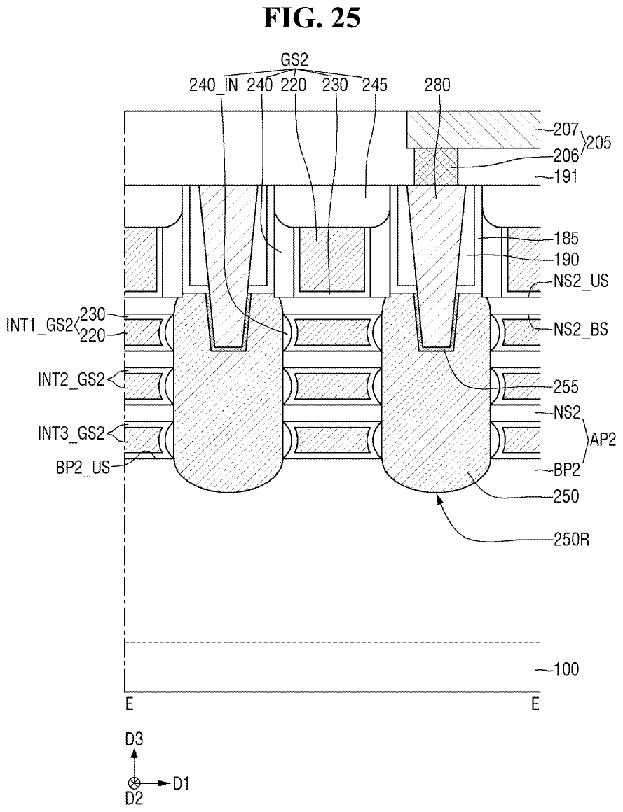

FIGS. 23 to 25 are diagrams for explaining a semiconductor device according to some embodiments. For reference, FIG. 23 is an exemplary plan view for describing a semiconductor device according to some embodiments. FIGS. 24 and 25 are cross-sectional views taken along E-E of FIG. 23.

Further, the cross-sectional view taken along A-A of FIG. 23 may be the same as one of FIGS. 2, 11, 13, 16, 17 and 19. In addition, the description of the first region I of FIG. 23 may be substantially the same as that described using FIGS. 1 to 22. Therefore, the following description will be provided mainly on a third region III of FIG. 23.

Referring to FIGS. 23 to 25, a semiconductor device according to some embodiments may include a first active pattern AP1, a plurality of first gate structures GS1, a first source/drain pattern 150, a second active patterns AP2, a plurality of second gate structures GS2, and a second source/drain pattern 250.

The substrate 100 may include a first region I and a second region II. The first region I may be a region in which s PMOS is formed, and the second region II may be a region in which an NMOS is formed.

The first active pattern AP1, the plurality of first gate structures GS1, and the first source/drain pattern 150 may be in the first region I of the substrate 100. The second active pattern AP2, the plurality of second gate structures GS2, and the second source/drain pattern 250 may be on the second region II of the substrate 100.

The second active pattern AP2 may include a second lower pattern BP2 and a plurality of second sheet patterns NS2. The plurality of second sheet patterns NS2 may be on the upper surface BP2_US of the second lower pattern BP2. Each second sheet pattern NS2 may include an upper surface NS2_US and a lower surface NS2_BS that are opposite to each other in the third direction D3.

Each of the second lower pattern BP2 and the second sheet pattern NS2 may include one of silicon or germanium which is an elemental semiconductor material, a group IV-IV compound semiconductor, or a group III-V compound semiconductor. In the semiconductor device according to some embodiments, the second lower pattern BP2 may be a silicon lower pattern including silicon, and the second sheet pattern NS2 may be a silicon sheet pattern including silicon.

The plurality of second gate structures GS2 may be on the substrate 100. The second gate structure GS2 may be on the second active pattern AP2. The second gate structure GS2 may intersect or cross the second active pattern AP2. The second gate structure GS2 may intersect the second lower pattern BP2. The second gate structure GS2 may wrap the respective second sheet patterns NS2. The second gate structure GS2 may include a plurality of inner gate structures INT1_GS2, INT2_GS2 and INT3_GS2 between the second sheet patterns NS2 adjacent to each other in the third direction D3, and between the second lower pattern BP2 and the second sheet pattern NS2. The second gate structure GS2 may include, for example, a second gate electrode 220, a second gate insulating film 230, a second gate spacer 240, and a second gate capping pattern 245.

In FIG. 24, the second gate spacer 240 is not between the plurality of inner gate structures INT1_GS2, INT2_GS2 and INT3_GS2 and the second source/drain pattern 250. The second gate insulating film 230 included in the inner gate structures INT1_GS2, INT2_GS2 and INT3_GS2 may be in contact with the second source/drain pattern 250.

In FIG. 25, the second gate structure GS2 may include an inner spacer 240_IN. The inner spacer 240_IN may be between the second sheet patterns NS2 adjacent to each other in the third direction D3, and between the second lower pattern BP2 and the second sheet pattern NS2. The inner spacer 240_IN may be in contact with the second gate insulating film 230 included in the inner gate structures INT1_GS2, INT2_GS2 and INT3_GS2. The inner spacer 240_IN may define a part or portion of the second source/drain recess 250R.

A second source/drain pattern 250 may be formed on the second active pattern AP2. The second source/drain pattern 250 may be formed on the second lower pattern BP2. The second source/drain pattern 250 may be connected to the second sheet pattern NS2. The second source/drain pattern 250 may be included in the source/drain of the transistor that uses the second sheet pattern NS2 as a channel region.

The second source/drain pattern 250 may be inside the second source/drain recess 250R. A bottom surface of the second source/drain recess 250R may be defined by the second lower pattern BP2. Side walls of the second source/drain recess 250R may be defined by a second nanosheet NS3 and a second gate structure GS3.

In FIG. 24, the second source/drain recess 250R may include a plurality of width extension regions 250R_ER. Each of the width extension region 250R_ER of second source/drain recess may be defined above the upper surface BP2_US of the second lower pattern.

In FIG. 25, the second source/drain recess 250R does not include a plurality of width extension regions (250R_ER of FIG. 24). The side walls of the second source/drain recess 250R may not have a wavy or undulating shape. The upper part of the side wall of the second source/drain recess 250R may have a width in the first direction D1 that decreases as a distance in the third direction D3 increases from the second lower pattern BP2.

The second source/drain patterns 250 may include an epitaxial pattern. The second source/drain pattern 250 may include, for example, silicon or germanium which is an elemental semiconductor material. Also, the second source/drain pattern 250 may include a binary compound or a ternary compound including at least two or more of carbon (C), silicon (Si), germanium (Ge), and tin (Sn), or a compound obtained by doping these elements with a group IV element. For example, the second source/drain pattern 250 may include, but not limited to, silicon, silicon-germanium, silicon carbide, and the like.

The second source/drain pattern 250 may include impurities doped into the semiconductor material. For example, the second source/drain pattern 250 may include n-type impurities. The doped n-type impurities may include at least one of phosphorous (P), arsenic (As), antimony (Sb) and bismuth (Bi).

The second source/drain contact 280 may be on the second source/drain pattern 250. The second source/drain contact 280 may be connected to the second source/drain pattern 250. A second contact silicide film 255 may be further disposed between the second source/drain contact 280 and the second source/drain pattern 250.

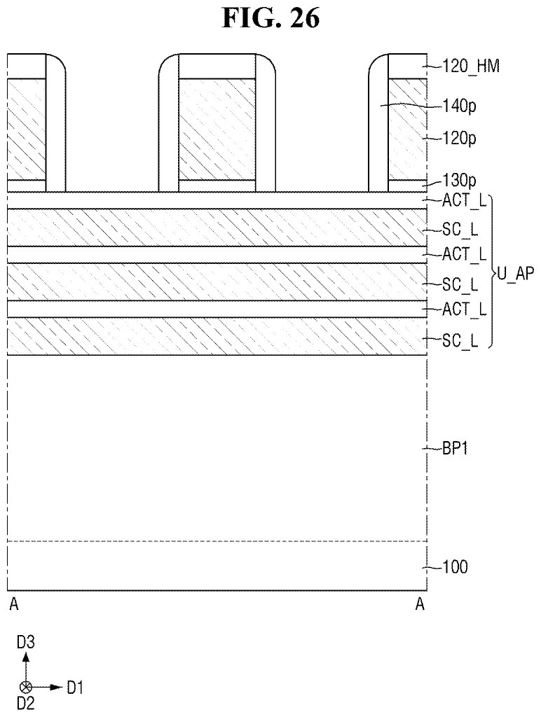

FIGS. 26 to 32 are intermediate step diagrams for describing a method for fabricating a semiconductor device according to some embodiments. For reference, FIGS. 26 to 32 may be cross-sectional views taken along A-A of FIG. 1.

Referring to FIG. 26, a first lower pattern BP1 and an upper pattern structure U_AP may be formed on the substrate 100.

The upper pattern structure U_AP may be on the first lower pattern BP1. The upper pattern structure U_AP may include a plurality of sacrificial patterns SC_L and a plurality of active patterns ACT_L that are alternately stacked on the first lower pattern BP1.

For example, the sacrificial pattern SC_L may include a silicon-germanium film. The active pattern ACT_L may include a silicon film.

Subsequently, a dummy gate insulating film 130p, a dummy gate electrode 120p, and a dummy gate capping film 120_HM may be formed on the upper pattern structure U_AP. The dummy gate insulating film 130p may include, for example, but is not limited to, silicon oxide. The dummy gate electrode 120p may include, for example, but is not limited to, polysilicon. The dummy gate capping film 120_HM may include, for example, but is not limited to, silicon nitride.

A pre-gate spacer 140p may be formed on side walls of the first dummy gate electrode 120p.

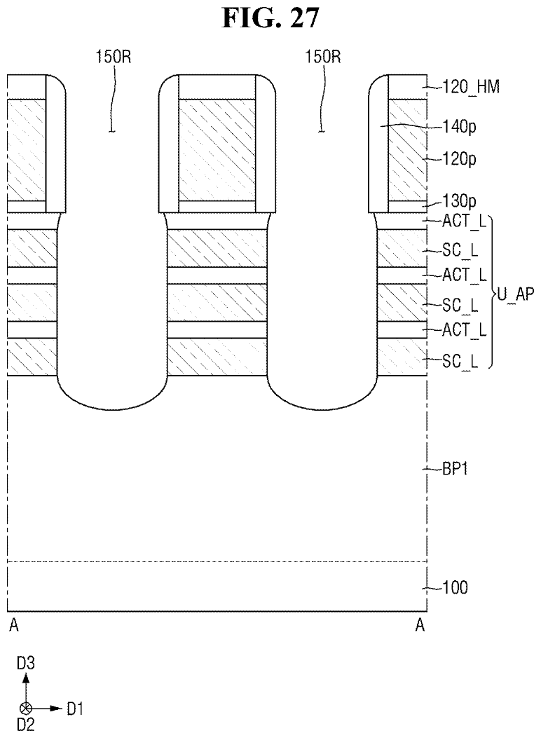

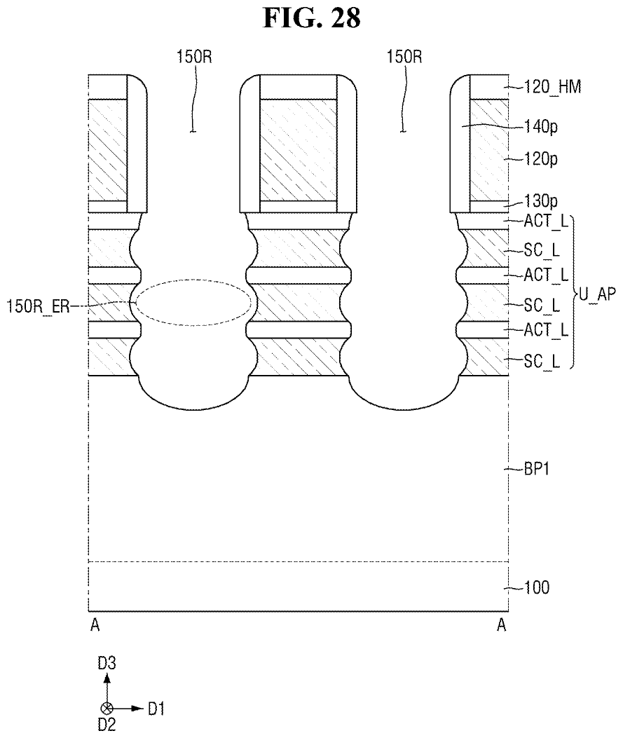

Referring to FIGS. 27 and 28, the first source/drain recess 150R may be formed in the upper pattern structure U_AP, using the dummy gate electrode 120p as a mask.

A part of the first source/drain recess 150R may be formed inside the first lower pattern BP1. A bottom surface of the first source/drain recess 150R may be defined by the first lower pattern BP1.

After forming the first source/drain recess 150R as in FIG. 27, the sacrificial pattern SC_L may be further etched. The width extension region 150R_ER of the first source/drain recess 150R may be formed accordingly.

The first source/drain recess 150R may include the multiple width extension regions 150R_ER. The side walls of the first source/drain recess 150R may have a wavy or undulating shape. However, the method for fabricating the first source/drain recess 150R including the multiple width extension regions 150R_ER is not limited to the aforementioned method.

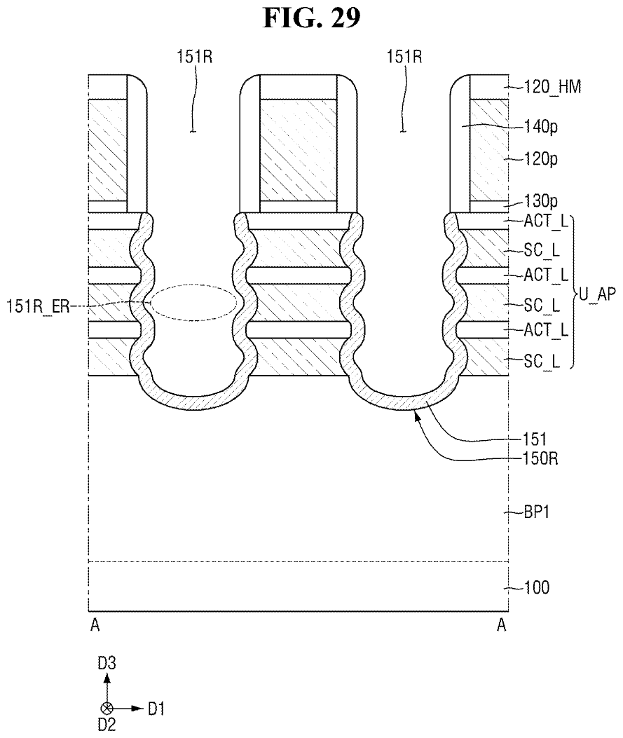

Referring to FIG. 29, the semiconductor liner film 151 may be formed on the first lower pattern BP1.

The semiconductor liner film 151 may be formed along the side walls and the bottom surface of the first source/drain recess 150R, and the semiconductor liner film 151 may conform to the side walls and the bottom surface of the first source/drain recess 150R.

The semiconductor liner film 151 may define a liner recess 151R corresponding to the side walls of the wavy or undulating first source/drain recess 150R. The side walls of the liner recess 151R may have a wavy or undulating shape that is similar to the side walls of the first source/drain recess 150R. The liner recess 151R may include the multiple width extension regions 151R_ER.

The semiconductor liner film 151 may be formed using an epitaxial growth method.

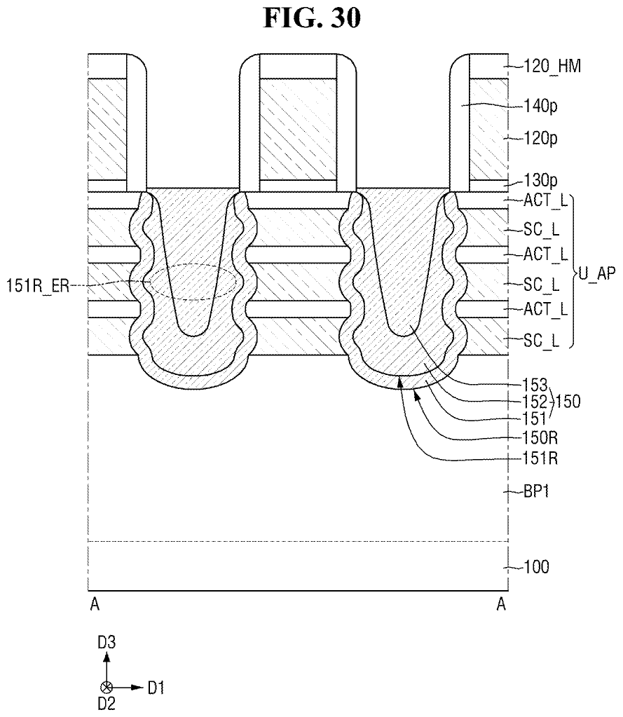

Referring to FIG. 30, the semiconductor insertion film 152 and the semiconductor filling film 153 may be formed on the semiconductor liner film 151. The semiconductor insertion film 152 and the semiconductor filling film 153 may be formed inside the liner recess 151R.

For example, the semiconductor insertion film 152 may be formed (e.g., continuously formed) along the profile of the liner recess 151R. In some embodiments, and in contrast to the shown example in FIG. 30, the semiconductor insertion film 152 may be formed into a shape as in FIG. 11 depending on the growth conditions of the semiconductor insertion film 152. As another example, the semiconductor insertion film 152 may be formed into a shape as in FIG. 13.

The semiconductor insertion film 152 and the semiconductor filling film 153 may each be formed using the epitaxial growth method.

Referring to FIG. 31, the source/drain etch stop film 185 and the interlayer insulating film 190 may be sequentially formed on the first source/drain pattern 150.

Subsequently, a part of the interlayer insulating film 190, a part of the source/drain etch stop film 185, and the dummy gate capping film 120_HM may be removed to expose the upper surface of the dummy gate electrode 120p. The first gate spacer 140 may be formed, while the upper surface of the dummy gate electrode 120p is exposed.

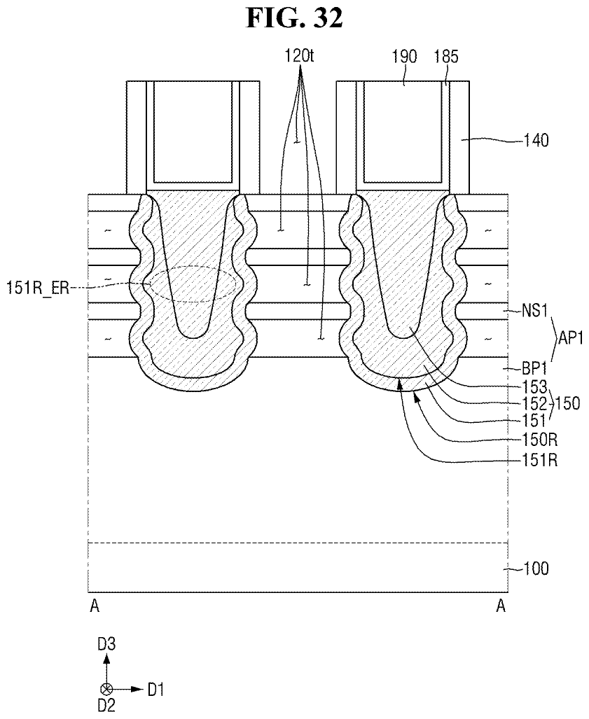

Referring to FIGS. 31 and 32, the upper pattern structure U_AP between the first gate spacers 140 may be exposed, by removing the dummy gate insulating film 130p and the dummy gate electrode 120p.

After that, the sacrificial pattern SC_L may be removed to form the first sheet pattern NS1. The first sheet pattern NS1 is connected to the first source/drain pattern 150. The first active pattern AP1 including the first lower pattern BP1 and the first sheet pattern NS1 is formed accordingly.

Also, the sacrificial pattern SC_L may be removed to form a gate trench 120t between the first gate spacers 140. When the sacrificial pattern SC_L is removed, a part of the first source/drain pattern 150 may be exposed.

In some embodiments, and in contrast to the shown example, a part of the semiconductor liner film 151 including silicon-germanium may also be removed, while the sacrificial pattern SC_L is removed. In such a case, the outer side wall of semiconductor liner film 151 may have the same shape as one of FIGS. 17 and 19.

In FIGS. 4 and 5, the thickness of the semiconductor liner film 151 at the portions of the inner gate structures INT1_GS1, INT2_GS1, and INT3_GS1 that are in contact with the first gate insulating film 130 may be as large as the thickness of the semiconductor liner film 151 at the portions that are in contact with the first sheet pattern NS1.

Meanwhile, while removing the sacrificial pattern SC_L, an etchant for removing the sacrificial pattern SC_L may permeate through the vicinity of the connecting side wall (140_CSW of FIG. 4) of the first gate spacer. Since the permeated etchant may etch the semiconductor insertion film 152 and/or the semiconductor filling film 153, the reliability and performance of the semiconductor device may be degraded.

However, since the semiconductor liner film 151 is formed conformally, the thickness of the semiconductor liner film 151 in the first direction D1 at which the semiconductor liner film 151 is in contact with the connecting side wall 140_CSW of the first gate spacer may increase.

As the contact thickness between the semiconductor liner film 151 and the first gate spacers 140 increases, the etchant for removing the sacrificial pattern SC_L can be prevented from permeating to the semiconductor insertion film 152 and/or the semiconductor filling film 153 through the connecting side walls 140_CSW of the first gate spacer. Accordingly, it may be possible to prevent the semiconductor insertion film 152 and/or the semiconductor filling film 153 from being etched by the etchant.

Next, referring to FIG. 2, the first gate insulating film 130 and the first gate electrode 120 may be formed inside the gate trench 120t. Also, the first gate capping pattern 145 may be formed.

In concluding the detailed description, those skilled in the art will appreciate that many variations and modifications may be made to the preferred embodiments without substantially departing from the principles of the present inventive concepts. Therefore, the disclosed preferred embodiments of the inventive concepts are used in a generic and descriptive sense only and not for purposes of limitation.

1. A semiconductor device comprising:
an active pattern which includes a lower pattern that extends in a first direction, and a plurality of sheet patterns spaced apart from the lower pattern in a second direction that is perpendicular to the first direction;
a plurality of gate structures which are on the lower pattern and spaced apart from each other in the first direction, each gate structure including a gate electrode and a gate insulating film; and
a source/drain pattern which is between a pair of the gate structures that are adjacent to each other in the first direction, the source/drain pattern including a semiconductor liner film and a semiconductor filling film on the semiconductor liner film,
wherein the semiconductor liner film and the semiconductor filling film include silicon-germanium,
wherein a germanium fraction of the semiconductor liner film is smaller than the germanium fraction of the semiconductor filling film,
wherein the semiconductor liner film includes an outer surface that is in contact with the plurality of sheet patterns, and an inner surface that faces the semiconductor filling film,
wherein a liner recess defined by the inner surface of the semiconductor liner film includes a plurality of width extension regions, and
wherein a width of each width extension region in the first direction increases and then decreases as a distance increases in the second direction from an upper surface of the lower pattern.

2. The semiconductor device of claim 1, wherein the inner surface of the semiconductor liner film includes a plurality of convex curved regions and a plurality of concave curved regions.

3. The semiconductor device of claim 1, wherein a first of the width extension regions is between a lower sheet pattern and an upper sheet pattern in the second direction, and wherein a point on which first width extension region has a maximum width in the first direction is located between the lower sheet pattern and the upper sheet pattern.

4. The semiconductor device of claim 1, wherein the source/drain pattern further includes a semiconductor insertion film formed along the inner surface of the semiconductor liner film,
wherein the semiconductor insertion film includes silicon germanium, and
wherein a germanium fraction of the semiconductor insertion film is between the germanium fraction of the semiconductor liner film and the germanium fraction of the semiconductor filling film.

5. The semiconductor device of claim 4, wherein the width of the semiconductor filling film in the first direction increases as a distance increases in the second direction from the lower pattern.

6. The semiconductor device of claim 4, wherein the semiconductor insertion film includes an outer surface that faces the inner surface of the semiconductor liner film, and an inner surface that faces the semiconductor filling film, and
wherein the inner surface of the semiconductor insertion film includes a plurality of convex curved regions and a plurality of concave curved regions.

7. The semiconductor device of claim 1, wherein the source/drain pattern further includes a plurality of semiconductor insertion films spaced apart from each other in the second direction,
wherein each of the semiconductor insertion films is between the semiconductor liner film and the semiconductor filling film,
wherein each semiconductor insertion film includes silicon germanium, and
wherein a germanium fraction of each semiconductor insertion film is greater than the germanium fraction of the semiconductor liner film and smaller than the germanium fraction of the semiconductor filling film.

8. The semiconductor device of claim 7, wherein the semiconductor filling film is in contact with the semiconductor liner film.

9. The semiconductor device of claim 7, wherein the inner surface of the semiconductor liner film includes a plurality of convex curved regions and a plurality of concave curved regions, and
wherein at least part of one of the semiconductor insertion films is in one of the concave curved regions.

10. The semiconductor device of claim 1, wherein an entirety of the inner surface of the semiconductor liner film is in contact with the semiconductor filling film.

11. The semiconductor device of claim 1, wherein the outer surface of the semiconductor liner film includes a plurality of convex curved regions and a plurality of concave curved regions,
wherein one of the concave curved regions is in contact with a corresponding one of the sheet patterns, and
wherein one of the convex curved regions is in contact with one of the gate insulating films of one of the gate electrodes.

12. The semiconductor device of claim 1, wherein the outer surface of the semiconductor liner film includes a plurality of planar regions and a plurality of concave curved regions,
wherein one of the concave curved regions is in contact with a corresponding one of the sheet patterns, and
wherein one of the planar regions is in contact with one of the gate insulating films of one of the gate electrodes.

13. The semiconductor device of claim 1, wherein the outer surface of the semiconductor liner film includes a plurality of first concave curved regions and a plurality of second concave curved regions,
wherein one of the first concave curved regions is in contact with one of the sheet patterns, and
wherein one of the second concave curved regions is in contact with one of the gate insulating films of one of the gate electrodes.

14. A semiconductor device comprising:
an active pattern which includes a lower pattern that extends in a first direction, and a plurality of sheet patterns spaced apart from the lower pattern in a second direction that is perpendicular to the first direction;
a plurality of gate structures which are on the lower pattern and spaced apart from each other in the first direction, each gate structure including a gate electrode and a gate insulating film; and
a source/drain pattern which is between a pair of the gate structures that are adjacent to each other in the first direction, the source/drain pattern including a semiconductor insertion film, and a semiconductor filling film on the semiconductor insertion film,
wherein the semiconductor insertion film and the semiconductor filling film include silicon-germanium,
wherein a germanium fraction of the semiconductor insertion film is less than the germanium fraction of the semiconductor filling film,
wherein the semiconductor insertion film includes an inner surface that is in contact with the semiconductor filling film, and an outer surface that faces the plurality of sheet patterns,
wherein the outer surface of the semiconductor insertion film includes a plurality of first convex curved regions and a plurality of first concave curved regions, and
wherein the outer surface of the semiconductor insertion film is not in contact with the plurality of sheet patterns.

15. The semiconductor device of claim 14, wherein the inner surface of the semiconductor insertion film includes a plurality of second convex curved regions and a plurality of second concave curved regions.

16. The semiconductor device of claim 14, wherein a width of the semiconductor filling film in the first direction increases as a distance increases in the second direction from the lower pattern.

17. The semiconductor device of claim 14, wherein the source/drain pattern includes a semiconductor liner film which surrounds the outer surface of the semiconductor insertion film and is in contact with the semiconductor insertion film, and
wherein the semiconductor liner film is in contact with the plurality of sheet patterns and the lower pattern.

18. (canceled)

19. A semiconductor device comprising:
an active pattern which includes a lower pattern that extends in a first direction, and a plurality of sheet patterns spaced apart from the lower pattern in a second direction perpendicular to the first direction;
a plurality of gate structures which are on the lower pattern and spaced apart in the first direction, each gate structure including a gate electrode and a gate insulating film; and
a source/drain pattern which is between a pair of the gate structures that are adjacent to each other in the first direction,
wherein each gate structure includes inner gate structure between the lower pattern and the sheet pattern in the second direction, and between each pair of the sheet patterns adjacent to each other in the second direction, each inner gate structure including the gate electrode and the gate insulating film,
wherein the source/drain pattern includes a semiconductor liner film, a semiconductor filling film on the semiconductor liner film, and a semiconductor insertion film between the semiconductor liner film and the semiconductor filling film,
wherein the semiconductor liner film, the semiconductor insertion film and the semiconductor filling film include silicon-germanium,
wherein a germanium fraction of the semiconductor insertion film is greater than a germanium fraction of the semiconductor liner film and less than a germanium fraction of the semiconductor filling film,
wherein the semiconductor liner film includes an outer surface which is in contact with the sheet pattern and the inner gate structure, and an inner surface which is in contact with the semiconductor insertion film, and
wherein the inner surface of the semiconductor liner film includes a plurality of convex curved regions and a plurality of concave curved regions.

20. The semiconductor device of claim 19, wherein the semiconductor insertion film includes a plurality of sub-semiconductor insertion films spaced apart in the second direction.

21. The semiconductor device of claim 19, wherein the semiconductor insertion film conforms to the inner surface of the semiconductor liner film.
